(19) United States
(12) Patent Application Publication
(10) Pub. No.: US 2025/0386719 A1
(43) Pub. Date: Dec. 18, 2025

(54) DISPLAY PANEL, METHOD OF MANUFACTURING THE SAME, AND ELECTRONIC DEVICE INCLUDING THE SAME

(71) Applicant: Samsung Display Co., Ltd., Yongin-si (KR)

(72) Inventors: Soo Min BAEK, Yongin-si (KR); Ju Hwa HA, Yongin-si (KR)

(21) Appl. No.: 19/195,579

(22) Filed: Apr. 30, 2025

(30) Foreign Application Priority Data
Jun. 17, 2024 (KR) 10-2024-0078199
Aug. 30, 2024 (KR) 10-2024-0117537

(51) Int. Cl. H10K 59/80; H10K 59/12

(52) U.S. Cl. CPC H10K 59/879; H10K 59/1201; H10K 59/873

(57) ABSTRACT

Embodiments of the present disclosure may provide a display panel including a substrate, a pixel circuit layer above the substrate, and including sub-pixel circuits of sub-pixels, a light-emitting element layer above the pixel circuit layer, and including light-emitting elements of the sub-pixels, an organic layer above the light-emitting element layer, and including refractive areas having different respective refractive indices above the light-emitting elements, and a cover window above the organic layer.

### CROSS-REFERENCE TO RELATED APPLICATION

The present application claims priority to, and the benefit of, Korean Patent Application No. 10-2024-0078199, filed on Jun. 17, 2024, and Korean Patent Application No. 10-2024-0117537, filed on Aug. 30, 2024, in the Korean Intellectual Property Office, the entire disclosures of which are incorporated herein by reference.

### BACKGROUND

### 1. Field

Embodiments of the present disclosure relate to a display panel, a method of manufacturing the same, and an electronic device including the same.

### 2. Description of the Related Art

With development of information technology, importance of a display device which is a connecting medium between a user and information is emphasized. In response, the use of display devices such as liquid crystal display devices and organic light-emitting display devices is increasing.

Various studies are being conducted on a technology for controlling the angle at which light is emitted from a display device (or display panel) as the display device displays an image in an area close to a user's eyes.

### SUMMARY

An object to be achieved by the present disclosure is to provide a display panel in which the angle of the emitted light is controlled, a method of manufacturing the same, and an electronic device including the same.

Embodiments of the present disclosure may provide a display panel including a substrate, a pixel circuit layer above the substrate, and including sub-pixel circuits of sub-pixels, a light-emitting element layer above the pixel circuit layer, and including light-emitting elements of the sub-pixels, an organic layer above the light-emitting element layer, and including refractive areas having different refractive indices above the light-emitting elements, and a cover window above the organic layer.

The organic layer may include a first area corresponding to a center of the substrate, a third area corresponding to an edge of the substrate, and a second area between the first area and the third area, and wherein the refractive areas are arranged in different orders in the first area, the second area, and the third area.

The refractive areas in the first area may be arranged in an order of a high refractive area, a middle refractive area, and a low refractive area in a direction away from a first one of the light-emitting elements in plan view.

A relationship between horizontal positions and corresponding ones of the refractive indices above the first one of the light-emitting elements in the first area may follow an upward convex quadratic function in which a largest one of the corresponding ones of the refractive indices is in a central area.

The refractive areas in the second area may be arranged in an order of a low refractive area, a high refractive area, and a middle refractive area in a direction away from a second one of the light-emitting elements in plan view.

The refractive areas in the third area may be arranged in an order of a low refractive area, a middle refractive area, and a high refractive area in a direction away from a third one of the light-emitting elements in plan view.

A relationship between a horizontal position and corresponding ones of the refractive indices above the third one of the light-emitting elements may follow a downward convex quadratic function in which a smallest of the corresponding ones of the refractive indices is in a central area.

The refractive indices may range from about 1.4 to about 1.6.

The first area may be configured to emit light in a normal direction of the substrate through the organic layer, wherein the second area is configured to emit light at a first angle with respect to the normal direction through the organic layer, and wherein the third area is configured to emit light at a second angle, which is greater than the first angle, with respect to the normal direction through the organic layer.

Embodiments of the present disclosure may provide a method of manufacturing a display panel, the method including forming a pixel circuit layer including sub-pixel circuits of sub-pixels above a substrate, forming a light-emitting element layer including light-emitting elements connected to the sub-pixel circuits above the pixel circuit layer, forming an organic layer including refractive areas having different refractive indices above the light-emitting elements, and arranging a cover window above the organic layer.

The forming of the organic layer may include irradiating a mask having a pattern with ultraviolet rays, and curing the organic layer.

The curing of the organic layer may include forming a low refractive area among the refractive areas by irradiating a first mask having a first pattern with ultraviolet rays for a first time, and forming a high refractive area among the refractive areas by irradiating a second mask having a second pattern with ultraviolet rays for a second time that is longer than the first time.

The forming of the low refractive area may include forming the low refractive area at a position relatively far from a first one of the light-emitting elements in a first area in plan view, and forming the low refractive area at a position relatively close to a second one of the light-emitting elements in a second area in plan view, wherein the first area corresponds to a center of the substrate, and wherein the second area corresponds to an edge of the substrate.

A corresponding one of the refractive indices of the low refractive area may be about 1.4 or more.

The forming of the high refractive area may include forming the high refractive area at a position relatively close to a first one of the light-emitting elements in a first area in plan view, and forming the high refractive area at a position relatively far from a second one of the light-emitting elements in a second area in plan view, wherein the first area corresponds to a center of the substrate, and wherein the second area corresponds to an edge of the substrate.

A corresponding one of the refractive indices of the high refractive area may be about 1.6 or less.

The mask may include a photoresist.

Embodiments of the present disclosure may provide an electronic device including a processor, a first display device configured to be controlled by the processor, and configured to display an image to a right eye, and a second display device configured to be controlled by the processor, and configured to display an image to a left eye, wherein the first display device and the second display device include an organic layer configured to emit light from light-emitting elements through refractive areas having different refractive indices.

The first display device and the second display device may include a display panel, the display panel including a substrate, a pixel circuit layer above the substrate, and including sub-pixel circuits of sub-pixels, a light-emitting element layer above the pixel circuit layer, and including the light-emitting elements of the sub-pixels, and a cover window above the organic layer, and wherein the organic layer is above the light-emitting element layer.

The organic layer may include a first area corresponding to a center of the substrate, a third area corresponding to an edge of the substrate, and a second area between the first area and the third area, and wherein the refractive areas are arranged in different orders in the first area, the second area, and the third area.

### BRIEF DESCRIPTION OF THE DRAWINGS

FIG. 1 is a system block diagram of a display device according to embodiments of the present disclosure.

FIG. 2 is a plan view according to one or more embodiments of the display panel of FIG. 1.

FIG. 3 is an exploded perspective view illustrating a part of the display panel of FIG. 2.

FIG. 4 is a drawing illustrating an angle at which light is emitted from a display panel according to embodiments of the present disclosure.

FIG. 5 is a drawing illustrating a plurality of areas divided according to an angle at which light is emitted from a display panel according to embodiments of the present disclosure.

FIG. 6 is a cross-sectional view around the first pixel of FIG. 5.

FIG. 7 is a cross-sectional view around the second pixel of FIG. 5.

FIG. 8 is a cross-sectional view around the third pixel of FIG. 5.

FIG. 9 is a cross-sectional view around the fourth pixel of FIG. 5.

FIG. 10 is a cross-sectional view around the fifth pixel of FIG. 5.

FIG. 11 is a drawing illustrating the relationship between a horizontal position on a light-emitting element and a refractive index in the first area.

FIG. 12 is a drawing illustrating the relationship between the horizontal position on the light-emitting element and the refractive index in the second area.

FIG. 13 is a drawing illustrating the relationship between the horizontal position on the light-emitting element and the refractive index in the third area.

FIG. 14A and FIG. 14B are drawings for explaining a method of forming a plurality of refractive areas in an organic layer.

FIG. 15 is a plan view illustrating one or more embodiments of the pixels of FIG. 3.

FIG. 16 is an example of a cross-sectional view of the pixel of FIG. 15 taken along the line I-I′.

FIG. 17 is a cross-sectional view taken along the line I-I′ of FIG. 15 according to one or more other embodiments of the present disclosure.

FIG. 18 is an enlarged view illustrating area A of FIG. 17.

FIG. 19 is a drawing illustrating a display system according to embodiments of the present disclosure.

FIG. 20 is a perspective view illustrating an application example of the display system of FIG. 19.

FIG. 21 is a drawing illustrating a head-mounted display device worn by a user.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” the another portion but also a case where there is further another portion between the portion and the another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

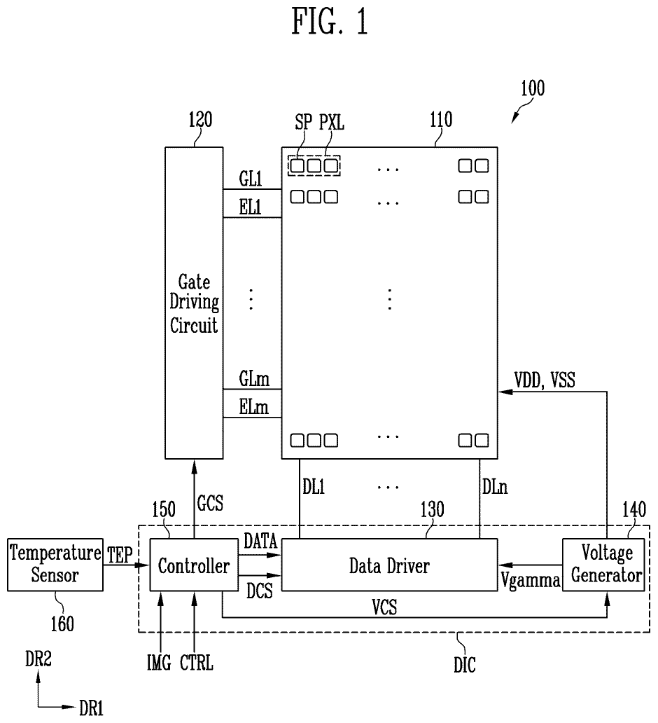

FIG. 1 is a system block diagram of a display device 100 according to embodiments of the present disclosure.

Referring to FIG. 1, the display device 100 according to embodiments of the present disclosure may include a display panel 110, a gate-driving circuit 120, a data driver 130, a voltage generator 140, a controller 150, and a temperature sensor 160.

The display panel 110 may include a plurality of sub-pixels SP. The display panel 110 may have first to m-th gate lines GL1 to GLm (m is an integer of 2 or more) connected to the plurality of sub-pixels SP. The display panel 110 may have first to n-th data lines DL1 to DLn (n is an integer of 2 or more) connected to the plurality of sub-pixels SP.

A plurality of sub-pixels SP may be connected to the gate-driving circuit 120 through first to m-th gate lines GL1 to GLm. A plurality of sub-pixels SP may be connected to the data driver 130 through first to n-th data lines DL1 to DLn.

Each of the plurality of sub-pixels SP may include at least one light-emitting element configured to generate light. Each of the plurality of sub-pixels SP may generate light of a color (for example, a corresponding color or a corresponding wavelength band) such as red, green, blue, cyan, magenta, yellow, or the like. Two or more of the plurality of sub-pixels SP may be included in one pixel PXL. For example, as illustrated in FIG. 1, three sub-pixels SP may be included in one pixel PXL.

The gate-driving circuit 120 may be connected to a plurality of sub-pixels SP (for example, a plurality of sub-pixels SP arranged in a first direction DR1 as a whole) through the first to m-th gate lines GL1 to GLm. The first direction DR1 may be, for example, a direction crossing from one side of the display panel 110 to the other side (for example, from the left to the right). The first direction DR1 may be, for example, a row direction.

The gate-driving circuit 120 may output gate signals (for example, gate signals of a turn-on level or a turn-off level) to the first to m-th gate lines GL1 to GLm in response to a gate control signal GCS. In the embodiments, the gate control signal GCS may include a start signal indicating the start of each frame, a horizontal synchronization signal for outputting gate signals in synchronization with the timing at which data signals are applied, and similar signals.

In the embodiments, the display panel 110 may further include first to m-th emission control lines EL1 to ELm connected to a plurality of sub-pixels SP. The first to m-th emission control lines EL1 to ELm may be arranged to extend in the row direction in the display panel 110. The plurality of sub-pixels SP may be connected to the first to m-th emission control lines EL1 to ELm. The gate-driving circuit 120 may include an emission control driver configured to control the first to m-th emission control lines EL1 to ELm. The emission control driver may operate under the control of the controller 150.

The gate-driving circuit 120 may be located on one side of the display panel 110. However, the embodiments are not limited thereto. For example, the gate-driving circuit 120 may be divided into two or more driving circuits that are physically and/or logically separated, and such driving circuits may be arranged on one side and the other side of the display panel 110 (for example, the other side of the display panel 110 opposite the one side). In this way, the gate-driving circuit 120 may be located in various forms within the display panel 110 or around the display panel 110 according to the embodiments.

The data driver 130 may be connected to a plurality of sub-pixels SP (for example, a plurality of sub-pixels SP arranged in the second direction DR2 as a whole) through the first to n-th data lines DL1 to DLn. The second direction DR2 may be, for example, a direction crossing from one side (for example, the lower side) to the other side (for example, the upper side) of the display panel 110. The second direction DR2 may be, for example, a column direction.

The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and similar signals.

The data driver 130 may apply data signals having grayscale voltages corresponding to the image data DATA to the first to n-th data lines DL1 to DLn by using voltages (for example, a gamma voltage Vgamma) from the voltage generator 140. When a gate signal (for example, a gate signal of a turn-on level) is applied to each of the first to m-th gate lines GL1 to GLm, data signals corresponding to image data DATA may be applied to the data lines DL1 to DLn. Each of the plurality of sub-pixels SP may receive a data signal applied at a corresponding timing in response to the gate signal (for example, a gate signal of a turn-on level). The plurality of sub-pixels SP may generate light corresponding to the input data signal. Accordingly, an image may be displayed on the display panel 110.

In embodiments, the gate-driving circuit 120 and the data driver 130 may each include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may receive an input voltage from outside the display device 100. The voltage generator 140 may adjust (for example, lower) the level of the received voltage and regulate the voltage whose level has been adjusted. The voltage generator 140 may be configured to generate a plurality of voltages.

The voltage generator 140 may generate, for example, a first power supply voltage VDD, a second power supply voltage VSS, a gamma voltage Vgamma, and similar voltages. The generated first and second power supply voltages VDD and VSS may be applied (for example, applied in common) to a plurality of sub-pixels SP. The first power supply voltage VDD may have a relatively high voltage level. The second power supply voltage VSS may have a lower voltage level than the first power supply voltage VDD. The generated gamma voltage Vgamma may be provided to the data driver 130. In other embodiments, the first power supply voltage VDD and/or the second power supply voltage VSS may be provided by an external device (for example, a power management integrated circuit (PMIC)) of the display device 100.

In one or more embodiments, the voltage generator 140 may generate a different voltage. For example, the voltage generator 140 may generate an initialization voltage that is applied (for example, applied in common) to a plurality of sub-pixels SP. For example, during a sensing operation for sensing electrical characteristics of transistors and/or light-emitting elements of a plurality of sub-pixels SP, a reference voltage (e.g., a predetermined reference voltage) may be applied to the first to n-th data lines DL1 to DLn, and a voltage generator 140 may generate such a reference voltage.

The controller 150 may be configured to control the overall operations of the display device 100. The controller 150 may receive input image data IMG input from the outside, and a control signal CTRL for controlling its display. The controller 150 may provide a gate control signal GCS, a data control signal DCS, and a voltage control signal VCS, and similar signals in response to the received control signal CTRL.

The controller 150 may convert input image data IMG to be suitable for the display device 100 or the display panel 110, and may output image data DATA. In embodiments, the controller 150 may align the input image data IMG to be suitable for the sub-pixels SP of the row unit, and may output image data DATA.

Two or more components among the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be functionally separated components within a single driver integrated circuit DIC. In other embodiments, at least one of the data driver 130, the voltage generator 140, and the controller 150 may be mounted within the driver integrated circuit DIC, and the other may be mounted and provided in an integrated circuit other than the driver integrated circuit DIC.

The temperature sensor 160 is configured to sense a temperature (for example, the temperature of the surroundings), and may generate temperature data TEP representing the sensed temperature. According to embodiments of the present disclosure, the temperature sensor 160 may be located on the display panel 110. According to embodiments of the present disclosure, the temperature sensor 160 may be located adjacent to the display panel 110 and/or the driver integrated circuit DIC. According to embodiments of the present disclosure, the display device 100 may include two or more temperature sensors 160.

The controller 150 may control various operations of the display device 100 in response to the temperature data TEP. In the embodiments, the controller 150 may adjust the brightness of the image output from the display panel 110 in response to the temperature data TEP. For example, the controller 150 may adjust at least one of the data signals, the first power supply voltage VDD, and the second power supply voltage VSS input to the display panel 110 by controlling components, such as the data driver 130 and/or the voltage generator 140.

The display device 100 according to one or more embodiments is a device that displays a moving image and/or a still image. The display device 100 may be applied to portable electronic devices, such as mobile phones, smartphones, tablet personal computers (PCs), mobile communication terminals, electronic notebooks, electronic books, portable multimedia players (PMPs), navigations, and ultra-mobile PCs (UMPCs). For example, the display device 100 may be applied to a display unit of a television, a laptop computer, a monitor, a billboard, or the Internet of Things (IoT) device. Alternatively, in one or more embodiments, the display device 100 may be applied to a smartwatch, a watch phone, a virtual reality (VR) device, an augmented reality (AR) device, and/or a head-mounted display device (HMD) (e.g., for implementing virtual reality and/or augmented reality).

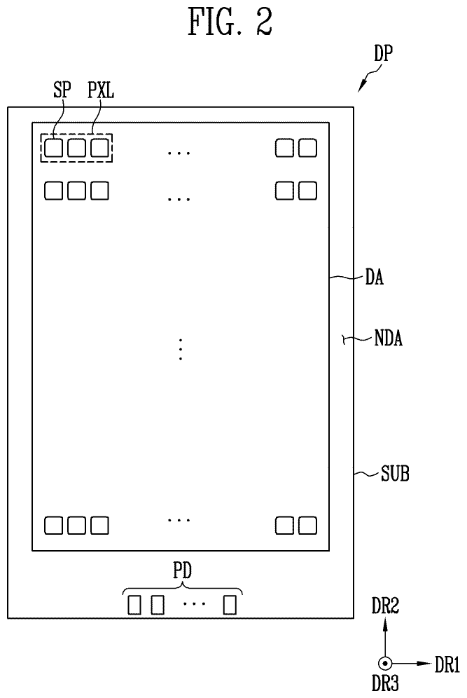

FIG. 2 is a plan view according to embodiments of the present disclosure of the display panel 110 of FIG. 1.

The display panel DP of FIG. 2 may be applied to the display panel 110 of FIG. 1.

Referring to FIG. 2, the display panel DP may include a display area DA and a non-display area NDA. The display panel DP may display an image through the display area DA. The non-display area NDA may be located around (for example, at the edge area, in plan view) the display area DA.

The display panel DP may include a substrate SUB, a plurality of sub-pixels SP arranged (or formed) on the substrate SUB, and a plurality of pads PD arranged (or formed) on the substrate SUB.

When the display panel DP according to the embodiments of the present disclosure is used as a display screen of a head-mounted display device (HMD), a virtual reality (VR) device, a mixed reality (MR) device, an augmented reality (AR) device, and similar devices, the display panel DP may be located very close to the user's eyes. In the embodiments, the sub-pixels SP may be required to be integrated at a relatively high density. To increase the integration of the sub-pixels SP, the substrate SUB according to the embodiments of the present disclosure may be provided as a silicon substrate. On the substrate SUB which is a silicon substrate, sub-pixels SP and/or other components of a display panel DP may be formed. A display device (e.g., display device 100 in FIG. 1) including other components of a display panel DP formed on a substrate SUB which is a silicon substrate may be referred to as an OLEDoS (OLED on Silicon) display device.

A plurality of sub-pixels SP may be arranged in a display area DA on the substrate SUB. Referring to FIG. 2, the sub-pixels SP may be arranged in a matrix form along a first direction DR1 and a second direction DR2 crossing the first direction DR1. However, the embodiments of the present disclosure are not limited thereto. For example, a plurality of sub-pixels SP according to embodiments of the present disclosure may be arranged in a zigzag form along the first direction DR1 and the second direction DR2. For example, a plurality of sub-pixels SP may be arranged in a PENTILE™ form. The first direction DR1 may be a row direction, and the second direction DR2 may be a column direction. Two or more sub-pixels SP among the plurality of sub-pixels SP may be included in one pixel PXL.

A component for controlling the sub-pixels SP may be arranged in a non-display area NDA on the substrate SUB. For example, wirings, such as the first to m-th gate lines GL1 to GLm and the first to n-th data lines DL1 to DLn of FIG. 1 may be arranged to extend to at least a part of the non-display area NDA.

At least one of the gate-driving circuit 120, the data driver 130, the voltage generator 140, the controller 150, and the temperature sensor 160 of FIG. 1 may be arranged (for example, integrated and arranged) in the non-display area NDA of the display panel DP.

In one or more embodiments, the gate-driving circuit 120 of FIG. 1 may be formed and arranged in the non-display area NDA of the display panel DP. In one or more other embodiments, the gate-driving circuit 120 may be implemented as a separate integrated circuit distinct from the display panel DP, and may be mounted in the non-display area NDA.

In one or more embodiments, the temperature sensor 160 of FIG. 1 may be located in the non-display area NDA to sense the temperature of the display panel DP. The temperature sensor 160 may be located, for example, at a vertex of the display panel DP or an area corresponding thereto. Two or more temperature sensors 160 may be arranged in the display panel DP.

The pads PD may be arranged in the non-display area NDA on the substrate SUB. The pads PD may be electrically connected to the sub-pixels SP through wires. For example, the pads PD may be connected to the sub-pixels SP via the first to n-th data lines (e.g., data lines DL1 to DLn in FIG. 1).

The pads PD may interface the display panel DP to other components of the display device (e.g., the display device 100 in FIG. 1). In embodiments, voltages and signals suitable for the operation of the components included in the display panel DP may be provided from the driver integrated circuit DIC of FIG. 1 via the pads PD. For example, the first to n-th data lines (e.g., data lines DL1 to DLn in FIG. 1) may be connected to the driver integrated circuit DIC via the pads PD. For example, the first and second power supply voltages (e.g., first and second power supply voltages VDD, VSS in FIG. 1) may be received from the driver integrated circuit DIC via the pads PD. In embodiments of the present disclosure where a gate-driving circuit (e.g., gate-driving circuit 120 in FIG. 1) is mounted on a display panel DP, a gate control signal (e.g., gate control signal GCS in FIG. 1) may be transmitted from a driver integrated circuit DIC to the gate-driving circuit 120 through pads PD.

In embodiments, a circuit board may be electrically connected to the pads PD using a conductive adhesive material, such as an anisotropic conductive film. At this time, the circuit board may be a flexible printed circuit board (FPCB) or a flexible film having a flexible material. The driver integrated circuit (the driver integrated circuit DIC in FIG. 1) may be mounted on the circuit board and electrically connected to the pads PD.

In embodiments, the display area DA may have various shapes. For example, the display area DA may have the shape of a closed loop including straight and/or curved edges. For example, the display area DA may have shapes, such as a polygon, a circle, a semicircle, an ellipse, and the like.

In embodiments, the display panel DP may have a flat display surface. In other embodiments, the display panel DP may have a display surface that is at least partially round. In embodiments, the display panel DP may be bendable, foldable, or rollable. The display panel DP including the substrate SUB may contain rigid or flexible substances.

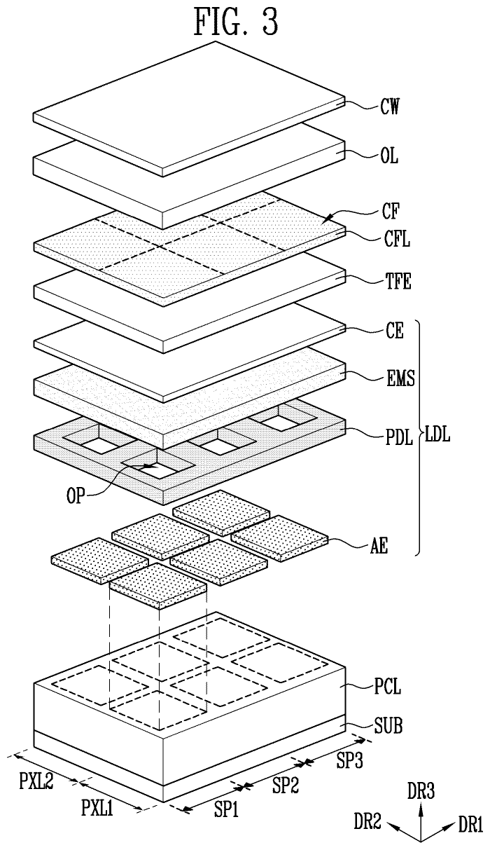

FIG. 3 is an exploded perspective view illustrating a portion of the display panel DP of FIG. 2.

In FIG. 3, a portion of a display panel DP corresponding to the first and second pixels PXL1 and PXL2 among the pixels PXL of FIG. 2 is schematically illustrated for a clear and concise explanation. The portions of the display panel DP corresponding to the remaining pixels may be configured in the same manner.

Referring to FIGS. 2 and 3, the first and second pixels PXL1 and PXL2 may be adjacent to each other in the second direction DR2. Each of the first and second pixels PXL1 and PXL2 may include a plurality of sub-pixels. Referring to FIG. 3, each of the first and second pixels PXL1 and PXL2 may include first, second, and third sub-pixels SP1, SP2, and SP3. However, the embodiments of the present disclosure are not limited thereto. For example, each of the first and second pixels PXL1 and PXL2 may include four sub-pixels, or may include two sub-pixels.

In FIG. 3, the first to third sub-pixels SP1 to SP3 are illustrated as having rectangular shapes and the same sizes when viewed in a third direction DR3 crossing the first and second directions DR1 and DR2 (for example, substantially perpendicular to the first and second directions DR1 and DR2). However, the embodiments are not limited thereto. The first to third sub-pixels SP1 to SP3 may be modified to have various shapes.

The display panel DP may include a substrate SUB, a pixel circuit layer PCL, a light-emitting element layer LDL, a thin film encapsulation layer TFE, a color filter layer CFL, an organic layer OL, and a cover window CW.

In embodiments, the substrate SUB may include a silicon wafer substrate formed using a semiconductor process. The substrate SUB may include a semiconductor substance suitable for forming circuit elements. For example, the semiconductor substance may include silicon, germanium, and/or silicon-germanium. The substrate SUB may be provided from a bulk wafer, an epitaxial layer, a silicon-on-insulator (SOI) layer, or a semiconductor-on-insulator (SeOI) layer. In other embodiments, the substrate SUB may include a glass substrate. In still other embodiments, the substrate SUB may include a polyimide (PI) substrate.

A pixel circuit layer PCL is located on the substrate SUB (as used herein, “located on” may mean “above”). The substrate SUB and/or the pixel circuit layer PCL may include insulating layers and conductive patterns arranged between the insulating layers. The conductive patterns of the pixel circuit layer PCL may function as at least a portion of the circuit elements, wirings, and the like. The conductive patterns may contain copper, but the embodiments are not limited thereto.

The circuit elements may include sub-pixel circuits of the first to third sub-pixels SP1 to SP3, respectively. The sub-pixel circuit may include two or more transistors and one or more capacitors. Each transistor may include a semiconductor portion including a source area, a drain area, and a channel area, and a gate electrode superimposed on the semiconductor portion (for example, a channel area of the semiconductor portion). In embodiments of the present disclosure where the substrate SUB is provided as a silicon substrate, the semiconductor portion may be included in the substrate SUB, and the gate electrode may be included in the pixel circuit layer PCL as a conductive pattern of the pixel circuit layer PCL. In embodiments of the present disclosure where the substrate SUB is provided as a glass substrate or a PI substrate, the semiconductor portion and the gate electrode may be included in the pixel circuit layer PCL. The capacitor may include electrodes that are spaced apart from each other (for example, facing each other). For example, each capacitor may include electrodes spaced apart from each other on a plane defined by the first and second directions DR1 and DR2. For example, the capacitor may include electrodes spaced apart from each other in a third direction DR3 with an insulating layer therebetween.

The wirings of the pixel circuit layer PCL may include signal lines, such as a gate line, an emission control line, and a data line, connected to each of the first to third sub-pixels SP1 to SP3.

The light-emitting element layer LDL may include anode electrodes AE, a pixel-defining layer PDL, an emission structure EMS, and a cathode electrode CE.

The anode electrodes AE may be located on the pixel circuit layer PCL. The anode electrodes AE may be connected (for example, contacted) to circuit elements of the pixel circuit layer PCL. The anode electrodes AE may contain an opaque conductive substance capable of reflecting light. However, the embodiments of the present disclosure are not limited thereto.

A pixel-defining layer PDL may be located on the anode electrodes AE. The pixel-defining layer PDL may include, or define, an opening OP exposing at least a portion of each of the anode electrodes AE. The opening OP of the pixel-defining layer PDL may correspond to the emission areas of each of the first to third sub-pixels SP1 to SP3.

In embodiments, the pixel-defining layer PDL may contain an inorganic substance. The pixel-defining layer PDL may include an inorganic layer (for example, a plurality of stacked inorganic layers). For example, the pixel-defining layer PDL may contain silicon oxide (SiOₓ) (x is a positive number) and/or silicon nitride (SiNₓ). In other embodiments, the pixel-defining layer PDL may include an organic layer containing an organic substance. However, the substance of the pixel-defining layer PDL according to embodiments of the present disclosure is not limited to the above.

The emission structure EMS may be located on the anode electrodes AE exposed by the opening OP of the pixel-defining layer PDL. The emission structure EMS may include one or more functional layers. The emission structure EMS may include functional layers, such as a light-generating layer (or emission layer) configured to generate light, an electron-transporting layer configured to transport electrons, and a hole-transporting layer configured to transport holes, for example.

In embodiments, the emission structure EMS may fill the opening OP of the pixel-defining layer PDL. In embodiments, the emission structure EMS may be located entirely on the pixel-defining layer PDL. For example, the emission structure EMS may extend across the first to third sub-pixels SP1 to SP3. At least some of the functional layers within the emission structure EMS may be separated or bent at boundaries between the first to third sub-pixels SP1 to SP3. However, the embodiments of the present disclosure are not limited thereto. For example, portions of the emission structure EMS corresponding to the first to third sub-pixels SP1 to SP3 may be separated from each other, and each of them may be arranged within the opening OP of the pixel-defining layer PDL.

The cathode electrode CE may be located on the emission structure EMS. The cathode electrode CE may extend across the first to third sub-pixels SP1 to SP3. The cathode electrode CE may be provided as a common electrode commonly connected to the first to third sub-pixels SP1 to SP3.

The cathode electrode CE may transmit light. For example, the cathode electrode CE may be a thin metal layer having a thickness sufficient to transmit light emitted from the emission structure EMS. The cathode electrode CE may be formed of a metal substance having a relatively thin thickness, or may be formed of a light-transmitting (for example, transparent) conductive substance. In embodiments, the cathode electrode CE may contain at least one of various transparent conductive substances, including indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO). However, the substance of the cathode electrode CE according to embodiments of the present disclosure is not limited to those described above. The cathode electrode CE may function as a half mirror that partially transmits and that partially reflects light emitted from the emission structure EMS. Any one of the anode electrodes AE, a portion of the emission structure EMS

overlapping it, and a portion of the cathode electrode CE overlapping it may be understood to be included in one light-emitting element. Each of the light-emitting elements of the first to third sub-pixels SP1 to SP3 may include one anode electrode AE, a portion of the emission structure EMS overlapping it, and a portion of the cathode electrode CE overlapping it. In each of the first to third sub-pixels SP1 to SP3, holes injected from the anode electrode AE and electrons injected from the cathode electrode CE are transported into the emission structure EMS to form excitons, and when the excitons transition from an excited state to a ground state, light may be generated. The brightness of the light may be determined depending on the amount of current flowing through the emission structure EMS. Depending on the configuration of the emission structure EMS, the wavelength band of light generated from the emission structure EMS may be determined.

A thin film encapsulation layer TFE is located on the cathode electrode CE. The thin film encapsulation layer TFE may cover the light-emitting element layer LDL and/or the pixel circuit layer PCL. The thin film encapsulation layer TFE may be configured to reduce or prevent penetration of oxygen and/or moisture into the light-emitting element layer LDL. In embodiments, the thin film encapsulation layer TFE may include a structure in which one or more inorganic films and one or more organic films are alternately stacked. For example, the inorganic film may contain silicon nitride, silicon oxide, or silicon oxynitride (SiOₓN_{y}). For example, the organic film may contain an organic insulating substance, such as an acrylic resin, an epoxy resin, a phenol resin, a polyamide resin, a polyimide resin, an unsaturated polyester resin, a polyphenylene ether resin, a polyphenylene sulfide resin, or benzocyclobutene (BCB) resin. However, the substances of the organic film and the inorganic film of the thin film encapsulation layer TFE are not limited to those described above.

To improve the encapsulation efficiency of the thin film encapsulation layer TFE, the thin film encapsulation layer TFE may further contain a thin film containing aluminum oxide (AlOₓ). A thin film containing aluminum oxide may be located on the upper surface of the thin film encapsulation layer TFE facing the color filter layer CFL and/or on the lower surface of the thin film encapsulation layer TFE facing the light-emitting element layer LDL. The thin film containing aluminum oxide may be formed through an atomic layer deposition (ALD) method. However, the embodiments of the present disclosure are not limited thereto. The thin film encapsulation layer TFE may further include a thin film formed of at least one of various substances suitable for improving encapsulation efficiency.

The color filter layer CFL may be located between the thin film encapsulation layer TFE and the organic layer OL. The color filter layer CFL may be configured to filter the light emitted from the emission structure EMS to selectively output light of a wavelength band corresponding to each sub-pixel. The color filter layer CFL may include color filters CF corresponding to each of the first to third sub-pixels SP1 to SP3. Each of the color filters CF may transmit light of a wavelength band corresponding to the corresponding sub-pixel. For example, the color filter corresponding to the first sub-pixel SP1 may transmit red color light, the color filter corresponding to the second sub-pixel SP2 may transmit green color light, and the color filter corresponding to the third sub-pixel SP3 may transmit blue color light. Depending on the light emitted from the emission structure EMS in each sub-pixel, at least some of the color filters CF may be omitted. According to embodiments of the present disclosure, the color filter layer CFL may be omitted. In embodiments, the color filters CF may overlap (for example, partially overlap) in a boundary area between the first to third sub-pixels SP1 to SP3. In other embodiments, the color filters CF may be spaced apart from each other in a boundary area between the first to third sub-pixels SP1 to SP3, and a black matrix may be provided between the color filters CF.

The organic layer OL may be located on the color filter layer CFL. The organic layer OL may cover the color filter layer CFL, the thin film encapsulation layer TFE, the emission structure EMS, and/or the pixel circuit layer PCL. The organic layer OL may contain various substances suitable for protecting its lower layers from foreign substances, such as dust and moisture.

In embodiments of the present disclosure, the organic layer OL may perform a function of guiding the direction in which light is emitted from the emission structure EMS. For example, in the central area of the display area (e.g., the display area DA in FIG. 2), the light emitted from the emission structure EMS may be output in the normal direction of the display surface through the organic layer OL. In the outer area (or edge area) of the display area DA, the light emitted from the emission structure EMS may be emitted in a direction tilted by an angle (e.g., a predetermined angle) with respect to the normal direction of the display surface. To this end, the organic layer OL may be divided into a plurality of areas, and may guide light to be emitted (or output) in different directions in the central area and the outer area. Accordingly, a lens for guiding the direction of light may be omitted. For example, damage to the round upper surface of the lens may be avoided, and a potential issue of light not being properly guided in a pre-designed direction due to the shape of the lens being deformed under high/low temperatures may be avoided.

A cover window CW may be located on the organic layer OL. The cover window CW may be configured to protect its lower layers. According to embodiments, the cover window CW may contain light-transmitting (for example, transparent) glass, metal, and the like. However, embodiments of the present disclosure are not limited thereto.

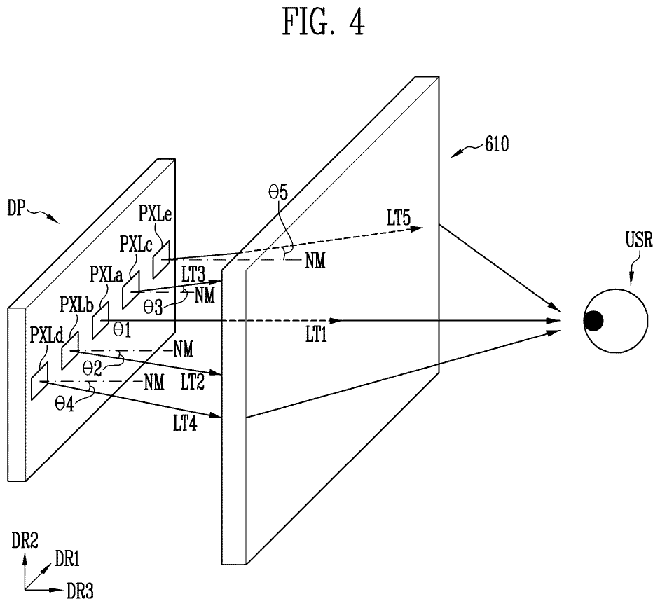

FIG. 4 is a drawing illustrating an angle at which light is emitted from a display panel DP according to embodiments of the present disclosure.

Referring to FIG. 4, first to fifth pixels PXLa, PXLb, PXLc, PXLd, and PXLe are illustrated in the display panel DP according to embodiments of the present disclosure.

The first pixel PXLa may represent pixels located in the central area (or the first area) of the display panel DP. The second pixel PXLb and the third pixel PXLc may represent pixels located in the area(s) (or the second area(s)) between the center and the edge of the display panel DP. The fourth pixel PXLd and the fifth pixel PXLe may represent pixels located in the edge area(s) (or the third area(s)) of the display panel DP.

The light LT1 emitted from the first pixel PXLa may be emitted from the display panel DP at an angle (for example, a predetermined angle) with respect to the display panel DP. Referring to FIG. 4, the angle formed by the light LT1 emitted from the first pixel PXLa and the normal NM of the display panel DP may be a first angle θ1. The first angle θ1 may be about 0°.

The light LT2 emitted from the second pixel PXLb may be emitted from the display panel DP at an angle (for example, a predetermined angle) with respect to the display panel DP. Referring to FIG. 4, the angle formed by the light LT2 emitted from the second pixel PXLb and the normal NM of the display panel DP may be a second angle θ2. The second angle θ2 may be an acute angle in a range greater than about 0°, and less than about 90°. For example, the second angle θ2 may be about 15°, but the embodiments of the present disclosure are not limited thereto.

The light LT3 emitted from the third pixel PXLc may be emitted from the display panel DP at an angle (for example, a predetermined angle) with respect to the display panel DP. Referring to FIG. 4, the angle formed by the light LT3 emitted from the third pixel PXLc and the normal NM of the display panel DP may be a third angle θ3. The third angle θ3 may be an acute angle in a range greater than about 0°, and less than about 90°. For example, the third angle θ3 may be about 15°, but the embodiments of the present disclosure are not limited thereto.

The light LT4 emitted from the fourth pixel PXLd may be emitted from the display panel DP at an angle (for example, a predetermined angle) with respect to the display panel DP. Referring to FIG. 4, the angle formed between the light LT4 emitted from the fourth pixel PXLd and the normal NM of the display panel DP may be a fourth angle θ4. The fourth angle θ4 may be an acute angle in a range greater than about 0°, and less than about 90°. For example, the fourth angle θ4 may be about 30°, but the embodiments of the present disclosure are not limited thereto. For example, the fourth angle θ4 may be about 40°. The light LT4 emitted from the fourth pixel PXLd may be mainly directed toward the outer side of the display panel DP.

The light LT5 emitted from the fifth pixel PXLe may be emitted from the display panel DP at an angle (for example, a predetermined angle) with respect to the display panel DP. Referring to FIG. 4, the angle formed between the light LT5 emitted from the fifth pixel PXLe and the normal NM of the display panel DP may be a fifth angle θ5. The fifth angle θ5 may be an acute angle in a range greater than about 0°, and less than about 90°. For example, the fifth angle θ5 may be about 30°, but the embodiments of the present disclosure are not limited thereto. For example, the fifth angle θ5 may be about 40°. The light LT5 emitted from the fifth pixel PXLe may be mainly directed toward the outer side of the display panel DP.

The first to third pixels PXLa, PXLb, and PXLc may be located between the fourth pixel PXLd and the fifth pixel PXLe. The first pixel PXLa may be located between the second pixel PXLb and the third pixel PXLc.

The light LT1 to LT5 emitted from the first to fifth pixels PXLa to PXLe may be incident on the external lens 610. The external lens 610 may refract the incident light LT1 to LT5. The light LT1 to LT5 refracted by the external lens 610 may travel toward the user USR. The external lens 610 may be configured to adjust the focal length. By the external lens 610, the user USR may see the display panel DP located close to the user USR more clearly. The external lens 610 may be implemented as, for example, a pancake lens, but the embodiments of the present disclosure are not limited thereto.

Depending on the distance between the first pixel PXLa located at the center of the display panel DP and any pixel located in any area of the display panel DP, the magnitude of the angle formed by the light emitted from the pixel and the normal NM of the display panel DP may vary. For example, the angle formed by the light emitted from the display panel DP and the normal NM of the display panel DP may become larger as it goes from the center area of the display panel DP to the peripheral area (for example, the edge area).

Referring to FIG. 4, the first angle θ1 formed by the light LT1 emitted from the first pixel PXLa located in the center area of the display panel DP and the normal NM of the display panel DP is about 0°, which may be the smallest when compared to the angle at which light is emitted from other pixels within the display panel DP. The angle (e.g., the fourth angle θ4 and the fifth angle θ5) formed by the light LT4 and LT5, which is emitted from the fourth pixel PXLd and the fifth pixel PXLe located in the edge area of the display panel DP, and the normal NM of the display panel DP may be the largest when compared to the angle at which light is emitted from other pixels within the display panel DP.

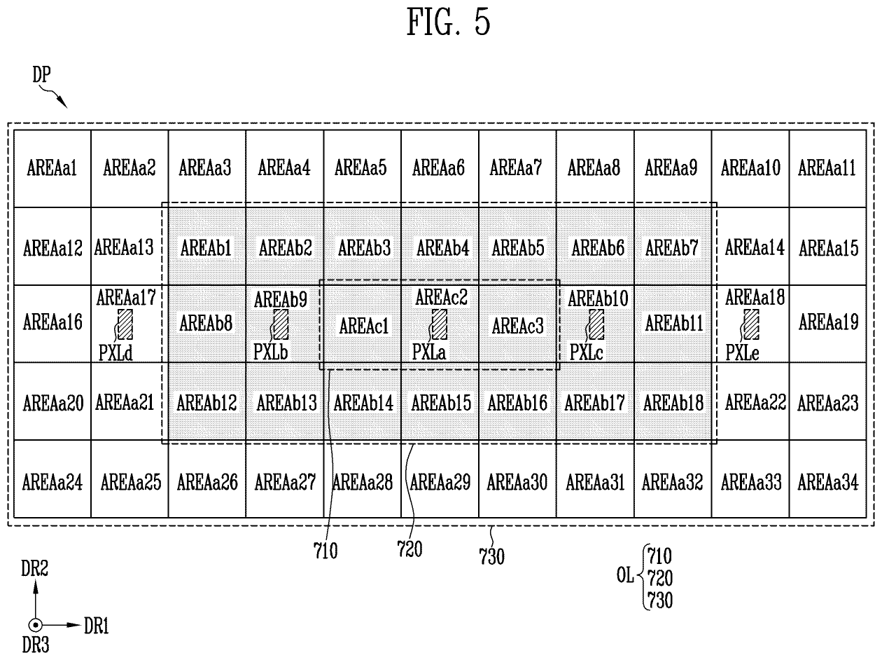

FIG. 5 is a drawing illustrating a plurality of areas divided according to the angle at which light is emitted from the display panel DP according to embodiments of the present disclosure.

The display panel DP may be divided into a plurality of areas according to the angle at which light is emitted. For example, the organic layer OL may be divided into a plurality of areas, and the direction of propagation of light emitted to the display surface of the display panel DP may vary depending on the arrangement order of the refractive areas in the organic layer OL.

Referring to FIG. 5, the organic layer OL may include a first area 710 corresponding to the central area of the display panel DP or the substrate (e.g., substrate SUB in FIG. 2), a third area 730 corresponding to the peripheral area (or edge area), and a second area 720 located between the first area 710 and the third area 730. Referring to FIG. 5, the organic layer OL is illustrated as including only three areas 710, 720, and 730, but the embodiments of the present disclosure are not limited thereto. For example, the organic layer OL may include four or more areas in which the directions in which light emitted from the display surface of the display panel DP travel are configured differently. For convenience of explanation, the organic layer OL is described below as including only the first to third areas 710, 720, and 730.

Referring to FIG. 4 described above, a first pixel PXLa may be located in the first area 710. A second pixel PXLb and a third pixel PXLc may be located in the second area 720. A fourth pixel PXLd and a fifth pixel PXLe may be located in the third area 730.

The first area 710 may be an area in which light emitted from the display surface of the display panel DP is emitted in the normal direction of the display panel DP. The second area 720 may be an area where light emitted from the display surface of the display panel DP is emitted at an angle (e.g., a predetermined angle) with respect to the normal line of the display panel DP. The third area 730 may be an area where light emitted from the display surface of the display panel DP is emitted at an angle (e.g., a predetermined angle) with respect to the display panel DP. Here, the angle formed by the light emitted from the second area 720 with respect to the normal line of the display panel DP may be less than the angle formed by the light emitted from the third area 730 with respect to the normal line of the display panel DP.

Each of the first to third areas 710 to 730 is illustrated as including a plurality of sub-areas, and such sub-areas may be set as examples to compare the relative sizes and widths of the respective areas. For example, the first area 710 may include three sub-areas AREAc1 to AREAc3 adjacent to each other in the first direction DR1. The second area 720 may include eighteen sub-areas AREAb1 to AREAb18 arranged to surround the first area 710. The third area 730 may include thirty-four sub-areas AREAa1 to AREAa34 arranged to surround the second area 720. The arrangement of the sub-areas in each of the first to third areas 710 to 730 may be changed according to the design of a person skilled in the art and is not limited to the method illustrated in FIG. 5.

The first area 710 may include three sub-areas AREAc1 to AREAc3, and the three sub-areas AREAc1 to AREAc3 may be arranged in a row. The first pixel PXLa may be arranged in the second sub-area AREAc2.

The second area 720 includes eighteen sub-areas AREAb1 to AREAb18, and may be arranged in three rows. For example, seven sub-areas AREAb1 to AREAb7 may be arranged in a first row, four sub-areas AREAb8 to AREAb11 may be arranged in a second row with the first area 710 therebetween, and the remaining seven sub-areas AREAb12 to AREAb18 may be arranged in a third row. The second pixel PXLb may be arranged in the ninth sub-area AREAb9. The third pixel PXLc may be arranged in the tenth sub-area AREAb10.

The third area 730 includes thirty-four sub-areas AREAa1 to AREAa34, and may be arranged in five rows. For example, eleven sub-areas AREAa1 to AREAa11 may be arranged in a first row. Four sub-areas AREAa12 to AREAa15 may be arranged in a second row with the second area 720 interposed therebetween. Four sub-areas AREAa16 to AREAa19 may be arranged in a third row with the second area 720 and the first area 710 interposed therebetween. Four sub-areas AREAa20 to AREAa23 may be arranged in a fourth row with the second area 720 interposed therebetween. Eleven sub-areas AREAa24 to AREAa34 may be arranged in a fifth row. A fourth pixel PXLd may be arranged in the seventeenth sub-area AREAa17. A fifth pixel PXLe may be arranged in the eighteenth sub-area AREAa18.

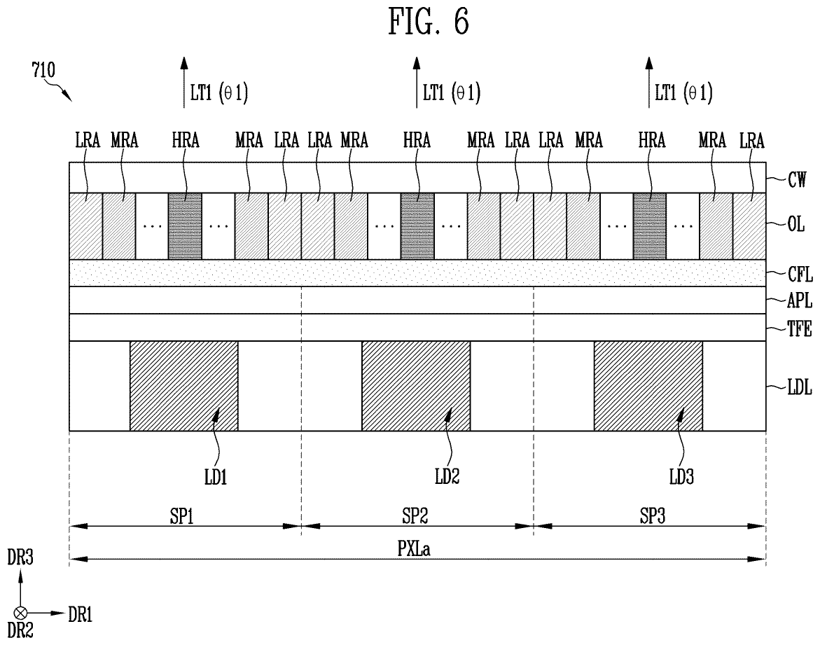

FIG. 6 is a cross-sectional view around the first pixel PXLa of FIG. 5.

Referring to FIG. 6, the light LT1 emitted from the first pixel PXLa toward the cover window CW (for example, in the third direction DR3) is illustrated. The light LT1 may be emitted in the normal NM direction (or in the vertical line direction) as a whole, and the first angle θ1 between the normal NM and the direction of propagation of the light LT1 may be about 0°.

An organic layer OL may be located on each of the first to third light-emitting elements LD1 to LD3. The organic layer OL may include a plurality of refractive areas. For example, the plurality of refractive areas may include a high refractive area HRA having the highest refractive index, a low refractive area LRA having the lowest refractive index, and a middle refractive area MRA having a refractive index that is between the refractive index of the high refractive area HRA and the refractive index of the low refractive area LRA.

In one or more embodiments, the refractive index of the high refractive area HRA may be about 1.6 or less. The refractive index of the low refractive area LRA may be about 1.4 or more. The refractive index of the middle refractive area MRA may be in a range of about 1.4 to about 1.6 while being greater than the refractive index of the low refractive area LRA and less than the refractive index of the high refractive area HRA.

In one or more embodiments, a plurality of middle refractive areas MRA having a refractive index between the refractive index of the high refractive area HRA and the refractive index of the low refractive area LRA may be provided. For example, if the refractive index of the high refractive area HRA is about 1.6 and the refractive index of the low refractive area LRA is about 1.4, a middle refractive area MRA having a refractive index of about 1.45, a middle refractive area MRA having a refractive index of about 1.5, and/or a middle refractive area MRA having a refractive index of about 1.55 may be provided. For convenience of explanation, the following description is given as an example of one middle refractive area MRA, but the embodiments of the present disclosure are not limited thereto.

A plurality of refractive areas may be located in each of the first to third sub-pixels SP1 to SP3. A high refractive area HRA may be located on a vertical line of each of the first to third light-emitting elements LD1 to LD3 located in the first area 710. The refractive indices of the refractive areas may gradually decrease in a direction away from the vertical line (e.g., away from the corresponding one of the light-emitting elements in plan view). For example, a high refractive area HRA may be located on a vertical line, and a high refractive area HRA, a middle refractive area MRA, and a low refractive area LRA may be arranged sequentially in a direction away from the vertical line.

The refractive indices of the high refractive area HRA, the middle refractive area MRA, and the low refractive area LRA in the first area 710 may be designed so that the light LT1 may travel along the vertical line of the cover window CW as a whole, and the refractive indices for this design may be calculated using Snell's law. As an example, the relationship between the distances from the vertical line of the light-emitting element to the high refractive area HRA, the middle refractive area MRA, and the low refractive area LRA and their refractive indices may follow an upward convex quadratic curve.

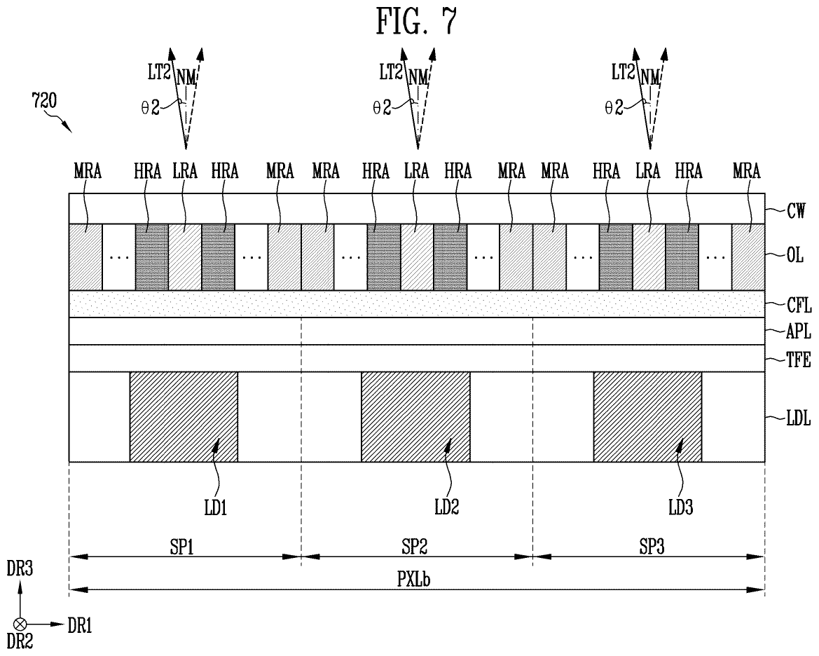

FIG. 7 is a cross-sectional view around the second pixel PXLb of FIG. 5.

Referring to FIG. 7, the light LT2 emitted from the second pixel PXLb toward the cover window CW (for example, in the third direction DR3) is illustrated. The light LT2 may be emitted in a direction having a second angle θ2 with respect to the normal NM as a whole, and the second angle θ2 may be about 15°. However, the embodiments of the present disclosure are not limited thereto.

A plurality of refractive areas may be located in each of the first to third sub-pixels SP1 to SP3. A low refractive area LRA may be located on a vertical line of each of the first to third light-emitting elements LD1 to LD3 located in the second area 720. In the direction away from the vertical line, the refractive indices of the refractive areas may increase from the refractive index of the low refractive area LRA to the refractive index of the high refractive area HRA, and then may decrease to the refractive index of the middle refractive area MRA. For example, the low refractive area LRA may be located on the vertical line, the high refractive area HRA may be located in the direction away from the vertical line, and the middle refractive area MRA may be located in the direction away from the high refractive area HRA.

The refractive indices of the high refractive area HRA, the middle refractive area MRA, and the low refractive area LRA in the second area 720 may be designed so that the light LT2 may proceed at an angle (e.g., a predetermined angle) with respect to the vertical line of the cover window CW, and the refractive indices for this design may be calculated using Snell's law. As an example, the relationship between the distances from the vertical line of the light-emitting element to the high refractive area HRA, the middle refractive area MRA, and the low refractive area LRA and their refractive indices may be represented by a combination of a downward convex quadratic curve and an upward convex quadratic curve.

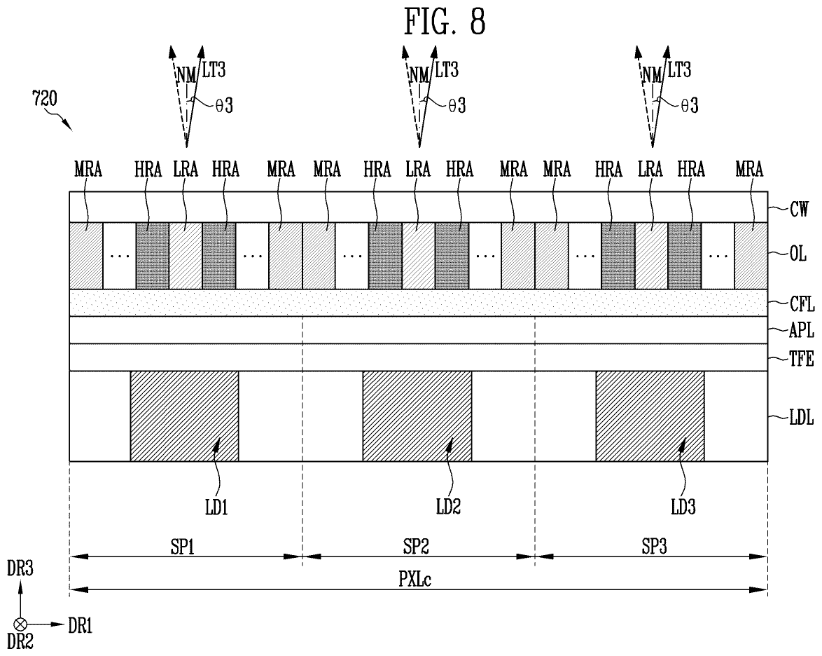

FIG. 8 is a cross-sectional view around the third pixel PXLc of FIG. 5.

Referring to FIG. 8, the light LT3 emitted from the third pixel PXLc toward the cover window CW (for example, in the third direction DR3) is illustrated. The light LT3 may be emitted in a direction having a third angle θ3 with respect to the normal NM as a whole, and the third angle θ3 may be about 15°. However, the embodiments of the present disclosure are not limited thereto.

Each of the first to third sub-pixels SP1 to SP3 may have a plurality of refractive areas. A low refractive area LRA may be located on a vertical line of each of the first to third light-emitting elements LD1 to LD3 located in the second area 720. In a direction away from the vertical line, the refractive indices of the refractive areas may increase from the refractive index of the low refractive area LRA to the refractive index of the high refractive area HRA, and then may decrease to the refractive index of the middle refractive area MRA. For example, the low refractive area LRA may be located on a vertical line, the high refractive area HRA may be located in a direction away from the vertical line, and the middle refractive area MRA may be located in a direction away from the high refractive area HRA.

In the second area 720, the refractive indices of the high refractive area HRA, the middle refractive area MRA, and the low refractive area LRA may be designed so that the light LT3 may travel at an angle (e.g., a predetermined angle) with respect to the vertical line of the cover window CW, and the refractive indices for this design may be calculated using Snell's law. As an example, the relationship between the distances from the vertical line of the light-emitting element to the high refractive area HRA, the middle refractive area MRA, and the low refractive area LRA and their refractive indices may be represented by a combination of a downward convex quadratic curve and an upward convex quadratic curve.

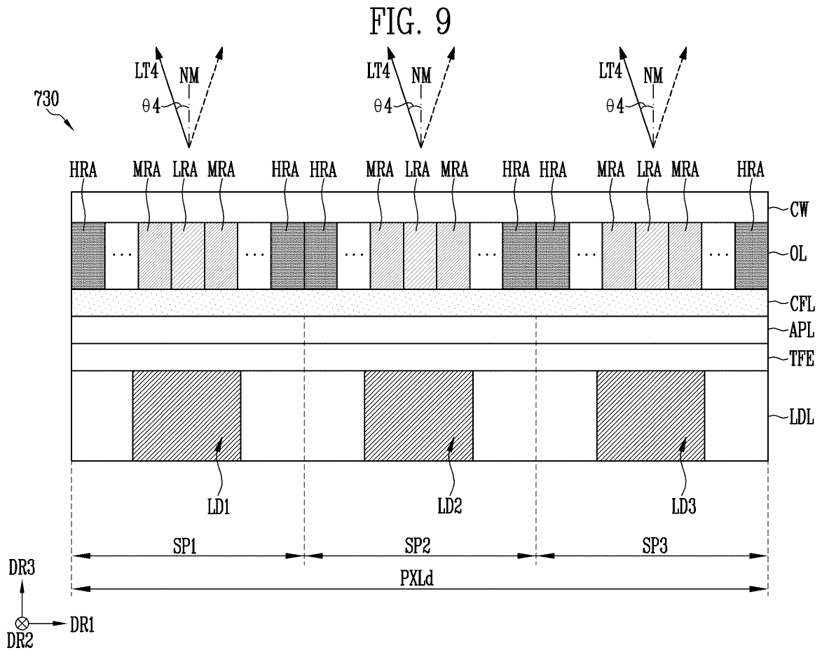

FIG. 9 is a cross-sectional view around the fourth pixel PXLd of FIG. 5.

Referring to FIG. 9, the light LT4 emitted from the fourth pixel PXLd toward the cover window CW (for example, in the third direction DR3) is illustrated. The light LT4 may be emitted in a direction having a fourth angle θ4 with respect to the normal NM as a whole, and the fourth angle θ4 may be about 30°. However, the embodiments of the present disclosure are not limited thereto.

A plurality of refractive areas may be located in each of the first to third sub-pixels SP1 to SP3. A low refractive area LRA may be located on a vertical line of each of the first to third light-emitting elements LD1 to LD3 located in the third area 730. In a direction away from the vertical line, the refractive indices of the refractive areas may increase from the refractive index of the low refractive area LRA to the refractive index of the high refractive area HRA. For example, the low refractive area LRA may be located on the vertical line, and the middle refractive area MRA and the high refractive area HRA may be sequentially located in a direction away from the vertical line.

In the third area 730, the refractive indices of the high refractive area HRA, the middle refractive area MRA, and the low refractive area LRA may be designed so that the light LT4 may travel at an angle (e.g., a predetermined angle) with respect to the vertical line of the cover window CW, and the refractive indices for this design may be calculated using Snell's law. As an example, the relationship between the distances from the vertical line of the light-emitting element to the high refractive area HRA, the middle refractive area MRA, and the low refractive area LRA and their refractive indices may follow a downward convex quadratic curve.

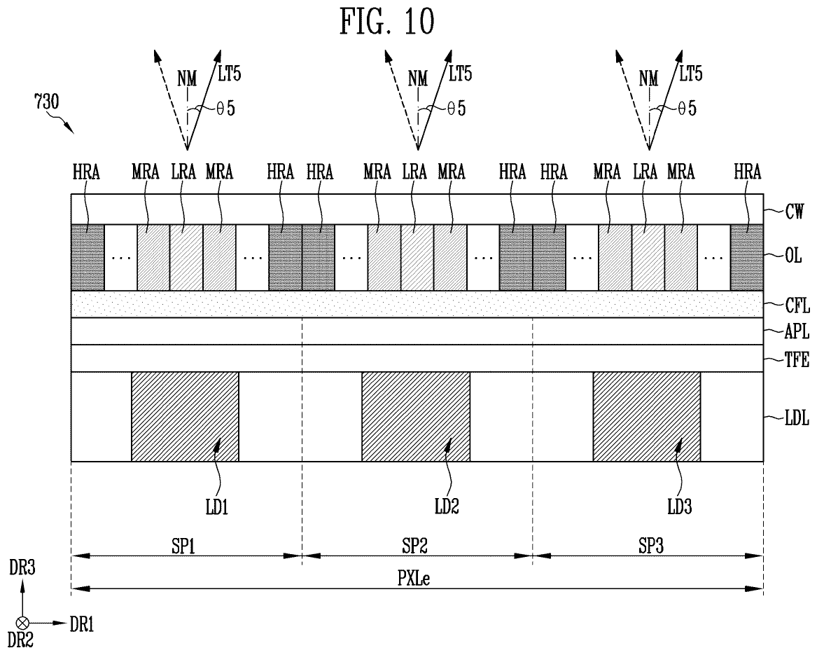

FIG. 10 is a cross-sectional view around the fifth pixel PXLe of FIG. 5.

Referring to FIG. 10, the light LT5 emitted from the fifth pixel PXLe toward the cover window CW (for example, in the third direction DR3) is illustrated. The light LT5 may be emitted in a direction having a fifth angle θ5 with respect to the normal NM as a whole, and the fifth angle θ5 may be about 30°. However, the embodiments of the present disclosure are not limited thereto.

Each of the first to third sub-pixels SP1 to SP3 may have a plurality of refractive areas. A low refractive area LRA may be located on a vertical line of each of the first to third light-emitting elements LD1 to LD3 located in the third area 730. In a direction away from the vertical line, the refractive indices of the refractive areas may increase from the refractive index of the low refractive area LRA to the refractive index of the high refractive area HRA. For example, the low refractive area LRA may be located on the vertical line, and the middle refractive area MRA and the high refractive area HRA may be sequentially located in a direction away from the vertical line.

In the third area 730, the refractive indices of the high refractive area HRA, the middle refractive area MRA, and the low refractive area LRA may be designed so that the light LT5 may travel at an angle (e.g., a predetermined angle) with respect to the vertical line of the cover window CW, and the refractive indices for this design may be calculated using Snell's law. As an example, the relationship between the distances from the vertical line of the light-emitting element to the high refractive area HRA, the middle refractive area MRA, and the low refractive area LRA and their refractive indices may follow a downward convex quadratic curve.

To more clearly explain the aforementioned FIGS. 6 to 10, the order in which the refractive areas are located in the first to third areas 710 to 730 will be explained by embodiments of the present disclosure in which the organic layer OL has a refractive area having a refractive index of about 1.4, a refractive area having a refractive index of about 1.43, a refractive area having a refractive index of about 1.47, a refractive area having a refractive index of about 1.53, and a refractive area having a refractive index of about 1.6. However, the refractive index of each of the plurality of refractive areas is only one example presented to clearly explain the embodiments of the present disclosure, and the embodiments of the present disclosure are not limited thereto.

The refractive area having a refractive index of about 1.4 may correspond to a low refractive area LRA, and the refractive area having a refractive index of about 1.6 may correspond to a high refractive area HRA. In addition, the refractive area having a refractive index of about 1.43, the refractive area having a refractive index of about 1.47, and the refractive area having a refractive index of about 1.53 may each correspond to a middle refractive area MRA.

In the first area 710, the refractive area having a refractive index of about 1.6, the refractive area having a refractive index of about 1.53, the refractive area having a refractive index of about 1.47, the refractive area having a refractive index of about 1.43, and the refractive area having a refractive index of about 1.4 may be sequentially arranged in a direction away from the vertical line of the light-emitting element.

In the second area 720, in an area close to the first area 710, a refractive area having a refractive index of about 1.4, a refractive area having a refractive index of about 1.6, a refractive area having a refractive index of about 1.53, a refractive area having a refractive index of about 1.47, and a refractive area having a refractive index of about 1.43 may be sequentially arranged in a direction away from the vertical line of the light-emitting element.

In the second area 720, in an intermediate area between the first area 710 and the third area 730, a refractive area having a refractive index of about 1.4, a refractive area having a refractive index of about 1.43, a refractive area having a refractive index of about 1.6, a refractive area having a refractive index of about 1.53, and a refractive area having a refractive index of about 1.47 may be sequentially arranged in a direction away from the vertical line of the light-emitting element.

In the second area 720, in an area close to the third area 730, a refractive area having a refractive index of about 1.4, a refractive area having a refractive index of about 1.43, a refractive area having a refractive index of about 1.47, a refractive area having a refractive index of about 1.6, and a refractive area having a refractive index of about 1.53 may be sequentially arranged in a direction away from the vertical line of the light-emitting element.

In the third area 730, a refractive area having a refractive index of about 1.4, a refractive area having a refractive index of about 1.43, a refractive area having a refractive index of about 1.47, a refractive area having a refractive index of about 1.53, and a refractive area having a refractive index of about 1.6 may be sequentially arranged in a direction away from the vertical line of the light-emitting element.

Through this, light may travel in the vertical direction of the organic layer OL in the central area of the organic layer OL as a whole, and light may travel at an angle (e.g., a predetermined angle) with respect to the vertical direction of the organic layer OL in the edge area of the organic layer OL as a whole.

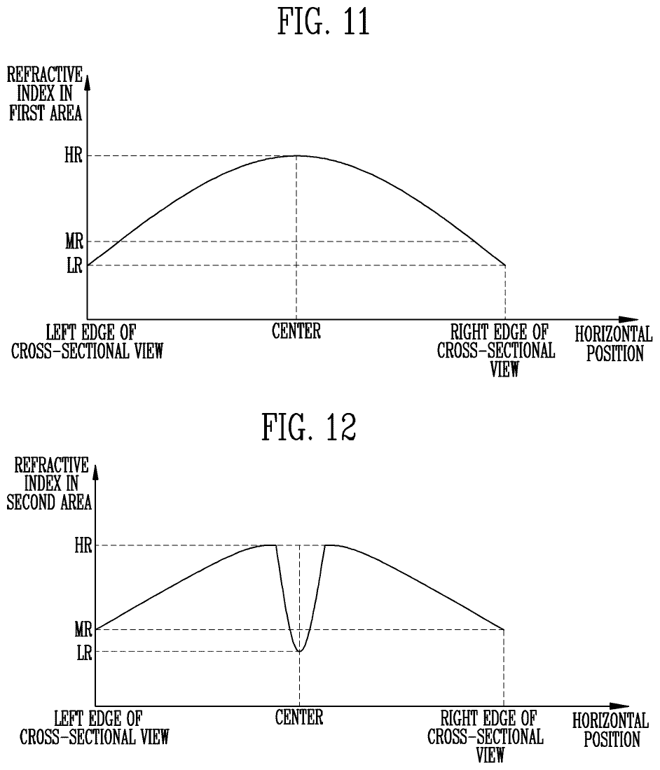

FIG. 11 is a drawing illustrating the relationship between the horizontal position on the light-emitting element and the refractive index in the first area.

The horizontal position on the light-emitting element is presented as the center, the left edge of the cross-section, and the right edge of the cross-section. The refractive index is presented as the low refractive index LR corresponding to the refractive index of the low refractive area, the middle refractive index MR corresponding to the refractive index of the middle refractive area, and the high refractive index HR corresponding to the refractive index of the high refractive area.

Referring to FIG. 11, the refractive index of the organic layer in the central area (or the area on the vertical line of the light-emitting element) on the light-emitting element in the first area (e.g., the first area 710 in FIG. 6) may have the high refractive index HR. As it goes toward the left and right edge, the refractive index may sequentially decrease in the order of the middle refractive index MR and the low refractive index LR. According to this, the relationship between the horizontal position on the light-emitting element and the refractive index in the first area 710 may follow an upward convex quadratic curve as a whole.

FIG. 12 is a drawing illustrating the relationship between the horizontal position on the light-emitting element and the refractive index in the second area.

Referring to FIG. 12, the refractive index of the organic layer in the central area (or the area on the vertical line of the light-emitting element) on the light-emitting element in the second area (e.g., the second area 720 in FIGS. 7 and 8) may have a low refractive index LR. As it goes toward the left and right edge, the refractive index may increase to a high refractive index HR. The refractive index may sequentially decrease from the high refractive index HR to the middle refractive index MR. According to this, the relationship between the horizontal position on the light-emitting element and the refractive index in the second area 720 may have a shape that is a combination of a downward convex quadratic curve and an upward convex quadratic curve.

FIG. 13 is a drawing illustrating the relationship between the horizontal position on the light-emitting element and the refractive index in the third area.

Referring to FIG. 13, in the third area (e.g., the third area 730 in FIGS. 9 and 10), the refractive index of the organic layer in the central area (or the area on the vertical line of the light-emitting element) on the light-emitting element may have a low refractive index LR. As it goes toward the left and right edges, the refractive index may sequentially increase in the order of the middle refractive index MR and the high refractive index HR. According to this, the relationship between the horizontal position on the light-emitting element and the refractive index in the third area 730 may follow a downward convex quadratic curve as a whole.

The “cross-section” of the cross-sectional view for defining the horizontal position of the X-axis on the graphs of FIGS. 11 to 13 may refer to a cross-section cut along a line connecting the center of the organic layer OL (or display panel DP) and the corresponding pixel illustrated in FIG. 5.

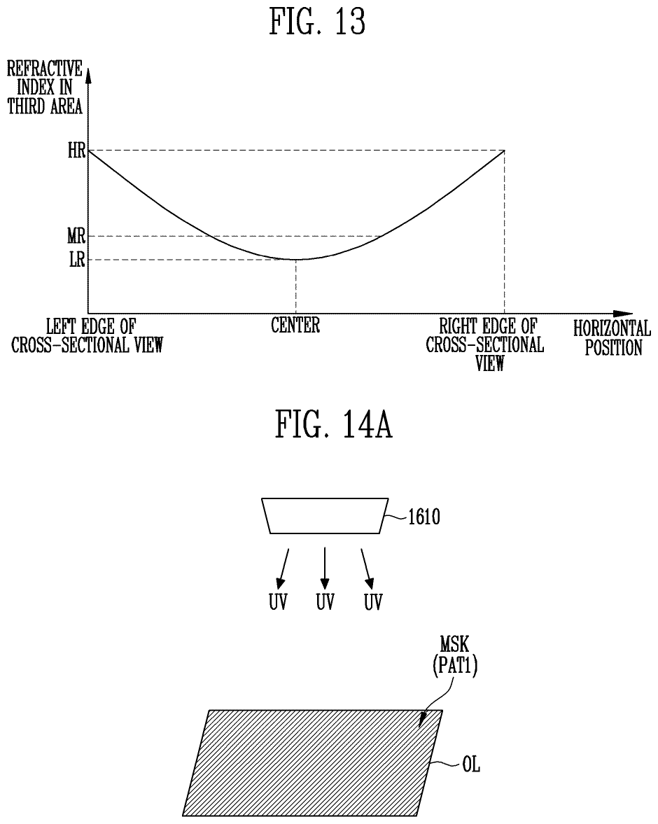

FIGS. 14A and 14B are drawings for explaining a method for forming a plurality of refractive areas in the organic layer OL.

Embodiments of the present disclosure may form refractive areas by irradiating a material (for example, resin and the like) forming the organic layer OL with ultraviolet (UV) rays to curing it. Depending on the length of the period for curing the material forming the organic layer OL, the refractive indices of the refractive areas may be designed differently.

For example, by curing the resin and the like for a short time, a refractive area (for example, a low refractive area) with a relatively low refractive index may be formed. For example, by curing resin and the like for a relatively long time, an area with a relatively high refractive index (for example, a high refractive area) may be formed.

Referring to FIG. 14A, a mask MSK having a first pattern PAT1 is located on an organic layer OL, and ultraviolet (UV) rays are irradiated for a relatively short time through a light source 1610 to form a low refractive area. The first pattern PAT1 may be, for example, a pattern in which an opening is formed in an area corresponding to the area where the low refractive area LRA illustrated in FIGS. 6 to 10 is located.

Referring to FIG. 14B, a mask MSK having a second pattern PAT2 is located on an organic layer OL, and ultraviolet (UV) rays are irradiated for a relatively long time through the light source 1610 to form a high refractive area. The second pattern PAT2 may be, for example, a pattern in which an opening is formed in an area corresponding to an area where a high refractive area HRA illustrated in FIGS. 6 to 10 is located.

In one or more embodiments, the mask MSK may include a photoresist.

By this, a plurality of refractive areas having various refractive indices may be formed in the organic layer OL.

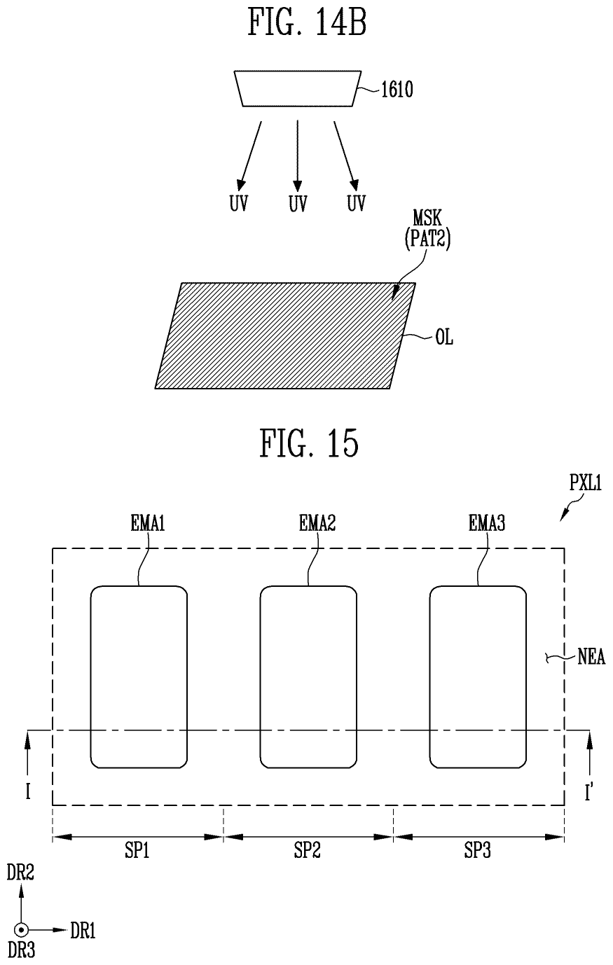

FIG. 15 is a plan view illustrating embodiments of the present disclosure of one of the pixels of FIG. 3.

In FIG. 15, for a clear and concise explanation, the first pixel PXL1 among the first and second pixels PXL1 and PXL2 of FIG. 3 is schematically illustrated. The remaining pixels may be configured similarly to the first pixel PXL1. The first pixel PXL1 may include first to third sub-pixels SP1 to SP3 arranged in the first direction DR1.

The first sub-pixel SP1 may include a first emission area EMA1, and a non-emission area NEA around the first emission area EMA1. The second sub-pixel SP2 may include a second emission area EMA2, and a non-emission area NEA around the second emission area EMA2. The third sub-pixel SP3 may include a third emission area EMA3, and a non-emission area NEA around the third emission area EMA3.

The first emission area EMA1 may be an area where light is emitted from a portion of an emission structure (e.g., the emission structure EMS in FIG. 3) corresponding to the first sub-pixel SP1. The second emission area EMA2 may be an area where light is emitted from a portion of an emission structure EMS corresponding to the second sub-pixel SP2. The third emission area EMA3 may be an area where light is emitted from a portion of the emission structure EMS corresponding to the third sub-pixel SP3. As described with reference to FIG. 3, each emission area may be understood as an opening OP of the pixel-defining layer PDL corresponding to each of the first to third sub-pixels SP1 to SP3.

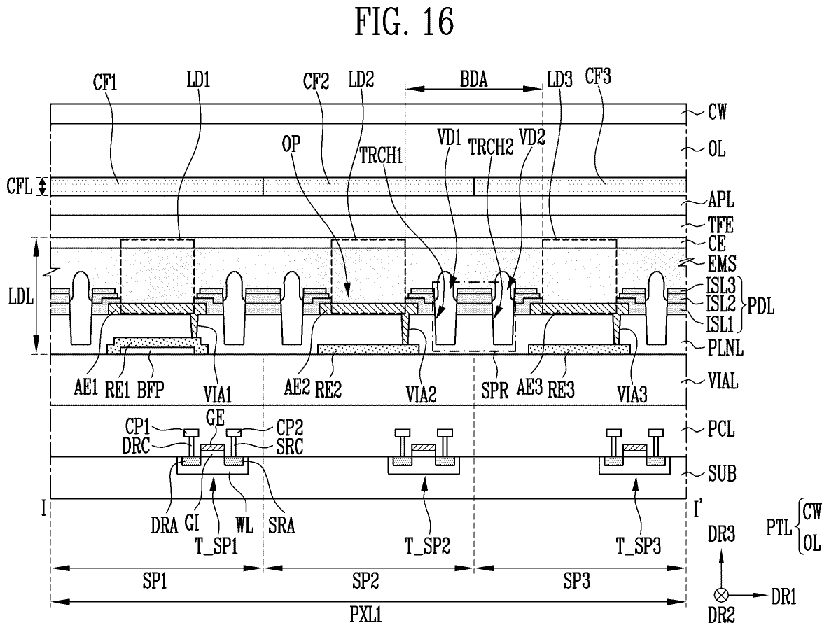

FIG. 16 is an example of a cross-sectional view of the pixel PXL1 of FIG. 15 taken along the line I-I′.

Referring to FIG. 16, the pixel PXL1 may include a substrate SUB and a pixel circuit layer PCL arranged on the substrate SUB.

The substrate SUB may include a silicon wafer substrate formed using a semiconductor process. For example, the substrate SUB may contain silicon, germanium, and/or silicon-germanium.

A pixel circuit layer PCL may be located on the substrate SUB. The substrate SUB and the pixel circuit layer PCL may include at least some of the circuit elements of each of the first to third sub-pixels SP1 to SP3. For example, the substrate SUB and the pixel circuit layer PCL may include the transistor T_SP1 of the first sub-pixel SP1, the transistor T_SP2 of the second sub-pixel SP2, and the transistor T_SP3 of the third sub-pixel SP3. The transistor T_SP1 of the first sub-pixel SP1 may be any one of the transistors included in the sub-pixel circuit of the first sub-pixel SP1. The transistor T_SP2 of the second sub-pixel SP2 may be any one of the transistors included in the sub-pixel circuit of the second sub-pixel SP2. The transistor T_SP3 of the third sub-pixel SP3 may be any one of the transistors included in the sub-pixel circuit of the third sub-pixel SP3. In FIG. 16, for a clear and concise description, one of the transistors of each of the first to third sub-pixels SP1 to SP3 is illustrated, and the remaining circuit elements of the sub-pixel circuit are not illustrated.

The transistor T_SP1 of the first sub-pixel SP1 may include a source area SRA, a drain area DRA, and a gate electrode GE.

The source area SRA and the drain area DRA may be arranged within a substrate SUB. The source area SRA and the drain area DRA may be arranged to be spaced apart from each other within a well WL of the substrate SUB. The well WL may be formed through an ion implantation process. The area between the source area SRA and the drain area DRA within the well WL may be defined as a channel area.

The gate electrode GE may overlap (for example, overlap in the third direction DR3) the channel area between the source area SRA and the drain area DRA. The gate electrode GE may be included in the pixel circuit layer PCL. The gate electrode GE may be separated from the well WL (or the channel area) by an insulating substance (for example, an insulating substance, such as a gate insulating layer GI). The gate electrode GE may contain a conductive substance.

The plurality of layers included in the pixel circuit layer PCL may include insulating layers, and conductive patterns arranged between the insulating layers. The conductive patterns of the pixel circuit layer PCL may include first and second conductive patterns CP1 and CP2. The first conductive pattern CP1 may be connected (for example, electrically connected) to the drain area DRA through a drain connection DRC penetrating one or more insulating layers. The second conductive pattern CP2 may be connected (for example, electrically connected) to the source area SRA via a source connection SRC penetrating one or more insulating layers.

As the gate electrode GE, the first conductive pattern CP1, and the second conductive pattern CP2 are connected to other circuit elements and/or wirings, the transistor T_SP1 of the first sub-pixel SP1 may be provided as one of the transistors of the sub-pixel circuit.

Each of the transistor T_SP2 of the second sub-pixel SP2 and the transistor T_SP3 of the third sub-pixel SP3 may be configured similarly to the transistor T_SP1 of the first sub-pixel SP1.

Similarly to that described above, the substrate SUB and/or the pixel circuit layer PCL may include circuit elements of each of the first to third sub-pixels SP1 to SP3.

A via layer VIAL may be located on the pixel circuit layer PCL. The via layer VIAL may cover the pixel circuit layer PCL. The via layer VIAL may have an overall flat surface (for example, a flat top surface). The via layer VIAL may be configured to flatten steps on the pixel circuit layer PCL. The via layer VIAL may contain at least one of silicon oxide (SiOₓ), silicon nitride (SiNₓ), and silicon carbon nitride (SiCN), but embodiments of the present disclosure are not limited thereto.

A light-emitting element layer LDL may be located on the via layer VIAL. The light-emitting element layer LDL may include first to third reflective electrodes RE1 to RE3, a planarization layer PLNL, first to third anode electrodes AE1 to AE3, a pixel-defining layer PDL, an emission structure EMS, and a cathode electrode CE.

The first to third reflective electrodes RE1 to RE3 may be respectively arranged in the first to third sub-pixels SP1 to SP3 on the via layer VIAL. Each of the first to third reflective electrodes RE1 to RE3 may contact a circuit element arranged in the pixel circuit layer PCL through a via penetrating the via layer VIAL.

The first to third reflective electrodes RE1 to RE3 may function as mirrors (for example, full mirrors) that reflect light emitted from the emission structure EMS toward the display surface (or cover window CW). The first to third reflective electrodes RE1 to RE3 may contain metal substances suitable for reflecting light. The first to third reflective electrodes RE1 to RE3 may contain at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and an alloy of two or more substances selected therefrom. However, the embodiments of the present disclosure are not limited thereto.

In embodiments, a buffer electrode may be located under each of the first to third reflective electrodes RE1 to RE3. The buffer electrode may improve electrical connection characteristics between the corresponding reflective electrode and the circuit elements of the pixel circuit layer PCL. The buffer electrode may have a multilayer structure. The buffer electrode may contain titanium (Ti), titanium nitride (TIN), tantalum nitride (TaN), and the like, but the embodiments of the present disclosure are not limited thereto. In embodiments, the corresponding reflective electrode may be located between the buffer electrodes (for example, between the multilayers forming the buffer electrode).

At least one of the first to third reflective electrodes RE1 to RE3 may be arranged on a buffer pattern BFP. The buffer pattern BFP may be configured to control the position of the reflective electrode (for example, the position in the third direction DR3 of the reflective electrode). The buffer pattern BFP may contain an inorganic substance, such as silicon carbon nitride, but embodiments of the present disclosure are not limited thereto. Referring to FIG. 16, by arranging the buffer pattern BFP, the position (for example, the height in the third direction DR3) of the corresponding reflective electrode may be adjusted. Referring to FIG. 16, the buffer pattern BFP may be arranged between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. At least a portion of the light emitted from the emission structure EMS may be amplified by reciprocating between the reflective electrode and the cathode electrode CE. This phenomenon may be understood as a resonance phenomenon. The amplified light may be output through the cathode electrode CE. The distance between each reflective electrode and the cathode electrode CE may be understood as a resonance distance for the light emitted from the emission structure EMS. The resonance distance may be adjusted by the buffer pattern BFP.

Referring to FIG. 16, the first sub-pixel SP1 may have a shorter resonance distance than other sub-pixels by the buffer pattern BFP. Light of a corresponding wavelength band (for example, red color) may be effectively and efficiently amplified by the adjusted resonance distance. Accordingly, the first sub-pixel SP1 may effectively and efficiently output light of the corresponding wavelength band.

Referring to FIG. 16, the buffer pattern BFP is illustrated as being provided to the first sub-pixel SP1 and not provided to, or omitted from, the second and third sub-pixels SP2 and SP3. However, the embodiments of the present disclosure are not limited thereto. The buffer pattern BFP may also be provided to at least one of the second and third sub-pixels SP2 and SP3, so that the resonance distance of at least one of the second and third sub-pixels SP2 and SP3 may be adjusted. For example, the first to third sub-pixels SP1 to SP3 may correspond to sub-pixels configured to emit light of red, green, and blue colors, respectively. The distance between the first reflective electrode RE1 and the cathode electrode CE may be shorter than the distance between the second reflective electrode RE2 and the cathode electrode CE. The distance between the second reflective electrode RE2 and the cathode electrode CE may be shorter than the distance between the third reflective electrode RE3 and the cathode electrode CE.

The planarization layer PLNL may be configured to planarize the steps between the first to third reflective electrodes RE1 to RE3. The planarization layer PLNL may be located on the via layer VIAL and the first to third reflective electrodes RE1 to RE3. The planarization layer PLNL may cover the first to third reflective electrodes RE1 to RE3 and the via layer VIAL as a whole. The planarization layer PLNL may have a planar surface (for example, a planar surface in the third direction DR3). In embodiments, the planarization layer PLNL may be omitted.

The first to third anode electrodes AE1 to AE3 may be arranged on the planarization layer PLNL. The first to third anode electrodes AE1 to AE3 may overlap (for example, overlap in the third direction DR3) the first to third reflective electrodes RE1 to RE3, respectively. The first to third anode electrodes AE1 to AE3 may have shapes similar to the first to third emission areas EMA1 to EMA3 of FIG. 4 when viewed in the third direction DR3. The first to third anode electrodes AE1 to AE3 are connected to the first to third reflective electrodes RE1 to RE3, respectively. The first anode electrode AE1 may be connected (for example, electrically connected) to the first reflective electrode RE1 through a first via VIA1 penetrating the planarization layer PLNL. The second anode electrode AE2 may be connected (for example, electrically connected) to the second reflective electrode RE2 through a second via VIA2 penetrating the planarization layer PLNL. The third anode electrode AE3 may be connected (for example, electrically connected) to the third reflective electrode RE3 through a third via VIA3 penetrating the planarization layer PLNL.

In embodiments, the first to third anode electrodes AE1 to AE3 may contain at least one of light-transmitting (for example, transparent) conductive substances, such as indium tin oxide, indium zinc oxide, zinc oxide, indium gallium zinc oxide, or indium tin zinc oxide. However, the substances of the first to third anode electrodes AE1 to AE3 are not limited thereto. For example, the first to third anode electrodes AE1 to AE3 may contain titanium nitride.

A pixel-defining layer PDL may be located on portions of the first to third anode electrodes AE1 to AE3 and the planarization layer PLNL. The pixel-defining layer PDL may include/define an opening OP exposing at least a portion of each of the first to third anode electrodes AE1 to AE3. The opening OP of the pixel-defining layer PDL may define an emission area in which light is emitted from each of the first to third sub-pixels SP1 to SP3. The pixel-defining layer PDL may be located in the non-emission area NEA of FIG. 15. The pixel-defining layer PDL may define the first to third emission areas EMA1 to EMA3 of FIG. 15.

In embodiments, the pixel-defining layer PDL may include a plurality of inorganic insulating layers. Each of the plurality of inorganic insulating layers forming the pixel-defining layer PDL may contain at least one of silicon oxide (SiOₓ) and silicon nitride (SiNₓ). For example, the pixel-defining layer PDL may include first to third inorganic insulating layers ISL1, ISL2, and ISL3 sequentially stacked, and the first to third inorganic insulating layers ISL1, ISL2, and ISL3 may contain silicon nitride, silicon oxide, and silicon nitride, respectively. However, the embodiments of the present disclosure are not limited thereto. The first to third inorganic insulating layers ISL1, ISL2, and ISL3 may have a step-shaped cross-section in an area adjacent to the opening OP.

The pixel PXL1 may include a separator SPR provided (or located) in a boundary area BDA between adjacent sub-pixels. In other words, a separator SPR may be provided in each of the boundary areas BDA between the sub-pixels SP of FIG. 2.

The separator SPR may form a discontinuity in the emission structure EMS at the boundary area BDA. For example, the emission structure EMS may be separated or bent at the boundary area BDA by the separator SPR.

The separator SPR may be provided in or on the pixel-defining layer PDL. The pixel-defining layer PDL may include one or more trenches TRCH1 and TRCH2 as the separator SPR at the boundary area BDA. In embodiments, as illustrated in FIG. 16, the one or more trenches TRCH1 and TRCH2 may penetrate the pixel-defining layer PDL, and may partially penetrate at least a portion of the planarization layer PLNL. In other embodiments, one or more trenches TRCH1 and TRCH2 may penetrate through the pixel-defining layer PDL and the planarization layer PLNL, and may partially penetrate at least a portion of the via layer VIAL. In still other embodiments, one or more trenches TRCH1 and TRCH2 may partially penetrate at least a portion of the planarization layer PLNL and/or at least a portion of the via layer VIAL, and at least a portion of the pixel-defining layer PDL may be arranged within one or more trenches TRCH1 and TRCH2.

Referring to FIG. 16, a plurality of trenches (for example, a first trench TRCH1 and a second trench TRCH2) are illustrated as being provided (or arranged) in the boundary area BDA. Below, for convenience of explanation, embodiments of the present disclosure in which two trenches TRCH1 and TRCH2 are provided in the boundary area BDA is described as an example. However, the embodiments of the present disclosure are not limited thereto. For example, the pixel-defining layer PDL may include a single (or one) trench in the boundary area BDA. As another example, the pixel-defining layer PDL may include three or more trenches in the boundary area BDA.

Due to the first and second trenches TRCH1 and TRCH2, a void may be formed as a discontinuity in the boundary area BDA. Referring to FIG. 16, discontinuities, such as the first void VD1 and the second void VD2 may be formed (or arranged) in the emission structure EMS. Some of the plurality of layers stacked within the emission structure EMS may be separated or bent by the first and second voids VD1 and VD2. For example, at least one charge generation layer included in the emission structure EMS may be separated by the first and second voids VD1 and VD2. Due to the first and second trenches TRCH1 and TRCH2, at least some of the emission structure EMS included in the first to third sub-pixels SP1 to SP3 may be partially separated.

Referring to FIG. 16, the first and second voids VD1 and VD2 are illustrated as being formed in the emission structure EMS in the boundary area BDA. However, this is only an example, and embodiments of the present disclosure are not limited thereto. For example, a concave valley may be formed in the emission structure EMS in the boundary area BDA. Depending on the shapes of the first and second trenches TRCH1 and TRCH2, the discontinuities formed in the emission structure EMS may be varied.

In the embodiments, the emission structure EMS may be formed through a process, such as vacuum deposition, inkjet printing, and the like. The emission structure EMS (or substances identical to the emission structure EMS) may be located on the bottom surfaces adjacent to the via layer VIAL among the first and second trenches TRCH1 and TRCH2.

The separator SPR may be provided in various variations so that the emission structure EMS may have a discontinuity in the boundary area BDA. In embodiments, inorganic insulating patterns may be additionally stacked on the pixel-defining layer PDL in the boundary area BDA without the first and second trenches TRCH1 and TRCH2. The width of the uppermost inorganic insulating pattern among the additionally stacked inorganic insulating patterns may be larger than the width of the inorganic insulating pattern arranged directly therebelow. For example, in embodiments of the present disclosure where the first to third inorganic insulating patterns are sequentially stacked from the pixel-defining layer PDL in the boundary area BDA, the width of the third inorganic insulating pattern arranged uppermost may be larger than the width of the second inorganic insulating pattern arranged directly therebelow. For example, the pixel-defining layer PDL may have a cross-section of a “T” shape or an “I” shape in the boundary area BDA. According to the pixel-defining layer PDL having a “T” shape or an “I” shape, at least some of the plurality of layers included in the emission structure EMS may be partially separated or bent at the boundary area BDA.

The emission structure EMS may be located on the anode electrodes AE exposed by the opening OP of the pixel-defining layer PDL. The emission structure EMS may fill the opening OP of the pixel-defining layer PDL, and may be located entirely over the first to third sub-pixels SP1 to SP3. As described above, at least some of the emission structure EMS may be partially separated or bent at the boundary area BDA by the separator SPR. Accordingly, when the display panel (e.g., the display panel 110 in FIG. 1) operates, the magnitude of the current (for example, leakage current) flowing from each of the first to third sub-pixels SP1 to SP3 to the adjacent sub-pixel through the layers included in the emission structure EMS may be reduced or eliminated. Accordingly, the first to third light-emitting elements LD1 to LD3 may operate with relatively high reliability.

The cathode electrode CE may be located on the emission structure EMS. The cathode electrode CE may be commonly provided (or located) to the first to third sub-pixels SP1 to SP3. The cathode electrode CE may function as a half mirror that partially transmits and partially reflects light emitted from the emission structure EMS.

A first anode electrode AE1, a portion of an emission structure EMS overlapping the first anode electrode AE1, and a portion of a cathode electrode CE overlapping the first anode electrode AE1 may form a first light-emitting element LD1. A second anode electrode AE2, a portion of an emission structure EMS overlapping the second anode electrode AE2, and a portion of a cathode electrode CE overlapping the second anode electrode AE2 may form a second light-emitting element LD2. A third anode electrode AE3, a portion of an emission structure EMS overlapping the third anode electrode AE3, and a portion of a cathode electrode CE overlapping the third anode electrode AE3 may form a third light-emitting element LD3.

A thin film encapsulation layer TFE may be located on the cathode electrode CE. The thin film encapsulation layer TFE may reduce or prevent oxygen and/or moisture and the like penetrating into the light-emitting element layer LDL.

The color filter layer CFL may be attached to the thin film encapsulation layer TFE via an adhesive layer APL. For example, the color filter layer CFL may be manufactured separately and attached to the thin film encapsulation layer TFE via an adhesive layer APL. The adhesive layer APL may further perform a function of protecting lower layers including the thin film encapsulation layer TFE.

The color filter layer CFL may include first to third color filters CF1 to CF3 corresponding to the first to third sub-pixels SP1 to SP3, respectively. The first to third color filters CF1 to CF3 may transmit light of different wavelength bands. For example, the first to third color filters CF1 to CF3 may transmit red, green, and blue light, respectively.

In embodiments, the first to third color filters CF1 to CF3 may partially overlap at the boundary area BDA. In other embodiments, the first to third color filters CF1 to CF3 may be spaced apart from each other, and a black matrix may be provided (or located) between each of the first to third color filters CF1 to CF3.

The organic layer OL may be located on the color filter layer CFL. The organic layer OL may contain various substances suitable for protecting its lower layers from foreign substances, such as dust and moisture. For example, the organic layer OL may include an inorganic insulating film. For example, the organic layer OL may contain an epoxy resin, but the embodiments are not limited thereto. The organic layer OL may include a low refractive area having a relatively low refractive index and a high refractive area having a relatively high refractive index. The refractive index of the low refractive area may be about 1.4 or more. The refractive index of the high refractive area may be about 1.6 or less.

A cover window CW may be located on the organic layer OL. According to embodiments, the cover window CW may contain glass, metal, or the like. However, embodiments of the present disclosure are not limited thereto. The cover window CW may be configured to protect components arranged thereunder. The cover window CW may be referred to as a sealing glass. The cover window CW may be in contact with the outside (for example, air).

The organic layer OL and the cover window CW may be included in a protective layer PTL.

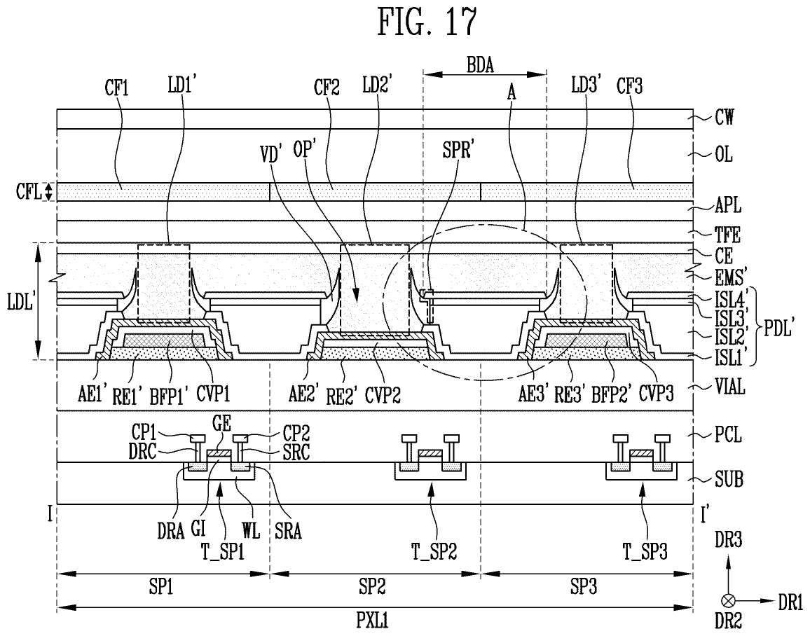

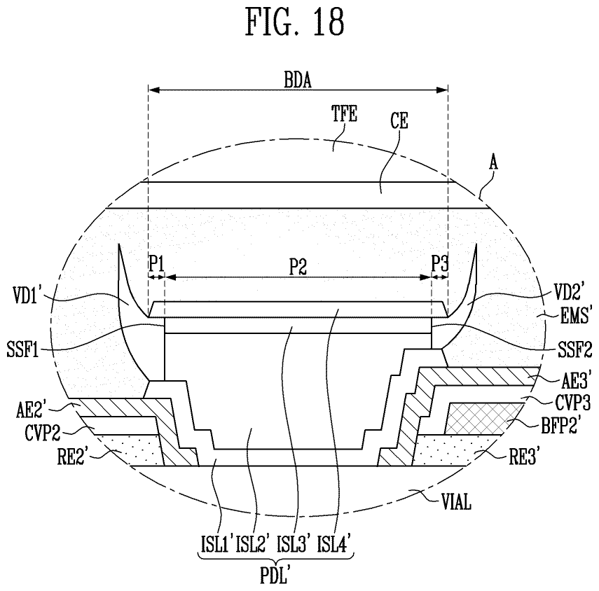

FIG. 17 is a cross-sectional view taken along the line I-I′ of FIG. 15 according to one or more other embodiments of the present disclosure. FIG. 18 is an enlarged view illustrating area A of FIG. 17.

Referring to FIG. 17, a pixel circuit layer PCL and a via layer VIAL are arranged on a substrate SUB. The substrate SUB, the pixel circuit layer PCL, and the via layer VIAL of FIG. 17 are configured similarly to the substrate SUB, the pixel circuit layer PCL, and the via layer VIAL of FIG. 16, respectively. Hereinafter, redundant descriptions are omitted.

A light-emitting element layer LDL′ is located on the via layer VIAL. The light-emitting element layer LDL′ may include first to third reflective electrodes RE1′ to RE3′, first and second buffer patterns BFP1′ and BFP2′, first to third cover patterns CVP1, CVP2, and CVP3, first to third anode electrodes AE1′ to AE3′, a pixel-defining layer PDL′, an emission structure EMS′, and a cathode electrode CE.

On the via layer VIAL, first to third reflective electrodes RE1′ to RE3′ are respectively arranged in the first to third sub-pixels SP1 to SP3. Each of the first to third reflective electrodes RE1′ to RE3′ may contact a circuit element located in the pixel circuit layer PCL through a via penetrating the via layer VIAL.

The first to third reflective electrodes RE1′ to RE3′ are configured to reflect light emitted from the emission structure EMS' toward the display surface (or the cover window CW). The first to third reflective electrodes RE1′ to RE3′ may contain metal substances suitable for reflecting light. The first to third reflective electrodes RE1′ to RE3′ may contain at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and an alloy of two or more substances selected therefrom, but the embodiments are not limited thereto.

In the embodiments, a connecting electrode may be further provided between each of the first to third reflective electrodes RE1′ to RE3′ and the via layer VIAL. The connecting electrode may improve the electrical connection characteristics between the corresponding reflective electrode and the circuit elements of the pixel circuit layer PCL. The connecting electrode may have a multilayer structure. The multilayer structure may contain titanium (Ti), aluminum (AI), titanium nitride (TiN), tantalum nitride (TaN), and the like, but the embodiments are not limited thereto. In the embodiments, the corresponding reflective electrode may be located between the multilayers of the connecting electrode.

A buffer pattern may be located on at least one of the first to third reflective electrodes RE1′ to RE3′. In the embodiments, the first and second buffer patterns BFP1′ and BFP2′ may be arranged on the first and third reflective electrodes RE1′ and RE3′, respectively. The heights of the first and third anode electrodes AE1′ and AE3′ in the third direction DR3 may be adjusted by the first and second buffer patterns BFP1′ and BFP2′. The first and second buffer patterns BFP1′ and BFP2′ may contain inorganic substances, such as silicon oxide (SiOₓ) and silicon nitride (SiNₓ), but the embodiments are not limited thereto.

First to third cover patterns CVP1 to CVP3 may be respectively arranged on the first to third reflective electrodes RE1′ to RE3′. In the first sub-pixel SP1, the first cover pattern CVP1 is located on the first reflective electrode RE1′ and the first buffer pattern BFP1′. In the second sub-pixel SP2, the second cover pattern CVP2 is located on the second reflective electrode RE2′. In the third sub-pixel SP3, the third cover pattern CVP3 is located on the third reflective electrode RE3′ and the second buffer pattern BFP2′. The first to third cover patterns CVP1 to CVP3 may be formed after the formation of the first and second buffer patterns BFP1′ and BFP2′ during the manufacturing process. The first to third cover patterns CVP1 to CVP3 may contain the same substance as the first and second buffer patterns BFP1′ and BFP2′. For example, the first to third cover patterns CVP1 to CVP3 may contain inorganic substances, such as silicon oxide (SiOₓ) and silicon nitride (SiNₓ), but the embodiments of the present disclosure are not limited thereto.

The first to third anode electrodes AE1′ to AE3′ are respectively arranged on the first to third cover patterns CVP1 to CVP3. In the embodiments, the first anode electrode AE1′ may cover the first cover pattern CVP1, the first buffer pattern BFP1′, and the first reflective electrode RE1′. The second anode electrode AE2′ may cover the second cover pattern CVP2 and the second reflective electrode RE2′. The third anode electrode AE3′ may cover the third cover pattern CVP3, the second buffer pattern BFP2′, and the third reflective electrode RE3′.

The first to third anode electrodes AE1′ to AE3′ may be electrically connected to the first to third reflective electrodes RE1′ to RE3′, respectively. For example, each anode electrode may be connected to an end (or edge) of a corresponding reflective electrode. However, the embodiments are not limited thereto. To improve electrical connection characteristics between the anode electrode and the reflective electrode, the anode electrode may be connected to the reflective electrode in various ways.

In the embodiments, the first to third anode electrodes AE1′ to AE3′ may contain at least one of transparent conductive substances, such as indium tin oxide, indium zinc oxide, zinc oxide (ZnOₓ), indium gallium zinc oxide (IGZO), or indium tin zinc oxide. However, the substance of the first to third anode electrodes AE1′ to AE3′ is not limited thereto. For example, the first to third anode electrodes AE1′ to AE3′ may contain titanium nitride.

The first to third anode electrodes AE1′ to AE3′ may have shapes similar to the first to third emission areas EMA1 to EMA3 of FIG. 15 when viewed in the third direction DR3 (e.g., in plan view).

The first to third anode electrodes AE1′ to AE3′ and the cathode electrode CE may partially reflect incident light. The light emitted from the emission layer of the emission structure EMS' may be amplified by reciprocating between the anode electrode and the cathode electrode CE, and may be output through the cathode electrode CE. For example, each anode electrode and the cathode electrode CE may provide a resonance structure in the corresponding sub-pixel. In this case, the distance between each anode electrode and the cathode electrode CE may be understood as a resonance distance for light emitted from the emission layer of the corresponding emission structure EMS′.

The first to third sub-pixels SP1 to SP3 may correspond to red, green, and blue, respectively. In this case, the height of the first and third anode electrodes AE1′ and AE3′ in the third direction DR3 may be higher than that of the second anode electrode AE2′ due to the first and second buffer patterns BFP1′ and BFP2′. Accordingly, the first and third sub-pixels SP1 and SP3 may have a shorter resonance distance than that of the second sub-pixel SP2 by the first and second buffer patterns BFP1′ and BFP2′. In this way, the resonance distance of each sub-pixel may be adjusted so that light of a wavelength range of a corresponding color is effectively and efficiently amplified.

In FIG. 17, the first and second buffer patterns BFP1′ and BFP2′ are illustrated as being respectively arranged below the first and third anode electrodes AE1′ and AE3′, but the embodiments are not limited thereto. For example, one of the first and second buffer patterns BFP1′ and BFP2′ may be omitted. As another example, both of the first and second buffer patterns BFP1′ and BFP2′ may be omitted. In this case, the resonance distance between each anode electrode and the cathode electrode CE may be the same. As another example, a buffer pattern may be located under each of the first to third anode electrodes AE1′ to AE3′. In this case, the buffer patterns arranged under each anode electrode may respectively have different thicknesses, and thus the resonance distances between each anode electrode and the cathode electrode CE may be different from each other. In this way, by providing a buffer pattern for adjusting the height of the anode electrode under at least one of the first to third anode electrodes AE1′ to AE3′, the resonance distance in each sub-pixel may be designed (for example, optimized).

A pixel-defining layer PDL′ is located on parts of the first to third anode electrodes AE1′ to AE3′ and a via layer VIAL. The pixel-defining layer PDL′ has an opening OP′ that exposes a part of each of the first to third anode electrodes AE1′ to AE3′. An area overlapping the pixel-defining layer PDL′ may be understood as a boundary area BDA between adjacent sub-pixels.

The pixel-defining layer PDL′ may include a plurality of sequentially stacked inorganic insulating layers. Each of the plurality of inorganic insulating layers may contain at least one of silicon oxide (SiOₓ) and silicon nitride (SiNₓ). However, the embodiments are not limited thereto. For example, the pixel-defining layer PDL′ may include an organic insulating layer.

In embodiments, the pixel-defining layer PDL′ may include first to fourth inorganic insulating layers ISL1′ to ISL4′. The first inorganic insulating layer ISL1′ may cover parts of the first to third anode electrodes AE1′ to AE3′ and the via layer VIAL. The second inorganic insulating layer ISL2′ may be located on the first inorganic insulating layer ISL1′. The third inorganic insulating layer ISL3′ may be located on the second inorganic insulating layer ISL2′. The fourth inorganic insulating layer ISL4′ may be located on the third inorganic insulating layer ISL3′. The first and third inorganic insulating layers ISL1′ and ISL3′ may contain silicon nitride (SiNₓ), and the second and fourth inorganic insulating layers ISL2′ and ISL4′ may contain silicon oxide (SiOₓ). However, the embodiments of the present disclosure are not limited thereto. In the embodiments, the first inorganic insulating layer ISL1′ may be omitted.

The pixel-defining layer PDL′ may include a separator SPR′ in a boundary area BDA between adjacent sub-pixels. The separator SPR′ may cause a discontinuity, such as a void VD′, to be formed in the emission structure EMS′. Due to the discontinuity, at least some of the plurality of layers included in the emission structure EMS' may be separated or bent.

The fourth inorganic insulating layer ISL4′ may be wider than the second and third inorganic insulating layers ISL2′ and ISL3′. In this case, the side surfaces of the second to fourth inorganic insulating layers ISL2′ to ISL4′ adjacent to the opening OP′ may be provided as separators SPR′.

Referring to FIGS. 17 and 18 together, the fourth inorganic insulating layer ISL4′ may include first to third portions P1 to P3. The second portion P2 may completely overlap the second and third inorganic insulating layers ISL2′ and ISL3′. The first portion P1 protrudes from the second portion P2 in a direction opposite to the first direction DR1. The third portion P3 protrudes from the second portion P2 in the first direction DR1. In this way, the fourth inorganic insulating layer ISL4′ may be wider than the second and third inorganic insulating layers ISL2′ and ISL3′. For example, during the manufacturing process, the second and third inorganic insulating layers ISL2′ and ISL3′ may be undercut so as not to include a portion overlapping the first and third portions P1 and P3. For example, each of the first and third portions P1 and P3 of the fourth inorganic insulating layer ISL4′ may have the shape of eaves on the second and third inorganic insulating layers ISL2′ and ISL3′.

In the boundary area BDA, the second and third inorganic insulating layers ISL2′ and ISL3′ may have the same width. However, the embodiments are not limited thereto, and the second and third inorganic insulating layers ISL2′ and ISL3′ may have different widths. For example, the second inorganic insulating layer ISL2′ may be wider than the third inorganic insulating layer ISL3′. As another example, the third inorganic insulating layer ISL3′ may be wider than the second inorganic insulating layer ISL2′.

In the second sub-pixel SP2, the first portion P1 of the fourth inorganic insulating layer ISL4′ and the first side SSF1 of the second and third inorganic insulating layers ISL2′ and ISL3′ may be provided as one separator SPR′. Accordingly, a first void VD1′, which is adjacent to a first portion P1 of the fourth inorganic insulating layer ISL4′ in the emission structure EMS′, may be formed. In the third sub-pixel SP3, the third portion P3 of the fourth inorganic insulating layer ISL4′ and the second side SSF2 of the second and third inorganic insulating layers ISL2′ and ISL3′ may be provided as another separator SPR′. Accordingly, a second void VD2′, which is adjacent to a third portion P3 of the fourth inorganic insulating layer ISL4′ in the emission structure EMS′, may be formed.

Some of the plurality of layers stacked in the emission structure EMS' may be separated or bent by the first and second voids VD1′ and VD2′. For example, at least one charge generation layer and at least one hole injection layer included in the emission structure EMS' may be separated by first and second voids VD1′ and VD2′. In this way, due to the separator SPR′, portions of the emission structure EMS' included in the first to third sub-pixels SP1 to SP3 may be at least partially separated from each other.

The pixel-defining layer PDL′ may include an additional separator so that the emission structure EMS' further includes a discontinuity in the boundary area BDA. In embodiments, the pixel-defining layer PDL′ may include one or more trenches as a separator in the boundary area BDA. The trenches may penetrate one or more of the first to fourth inorganic insulating layers ISL1′ to ISL4′. Due to the trenches, some of the layers stacked within the emission structure EMS′, for example, at least one charge generation layer and at least one hole injection layer, may be separated or bent. In embodiments, the emission structure EMS' may have a structure in which three light-emitting units, each including an emission layer, are stacked, and two charge generation layers may be arranged between the three light-emitting units. In these embodiments, the pixel-defining layer PDL′ may include one or more trenches in the boundary area BDA.

Referring again to FIG. 17, the emission structure EMS' may be located on the anode electrodes exposed by the opening OP′ of the pixel-defining layer PDL′. The emission structure EMS' may fill the opening OP′ of the pixel-defining layer PDL′, and may be located entirely over the first to third sub-pixels SP1 to SP3. As described above, the emission structure EMS' may be separated or bent in the boundary area BDA or in the area adjacent to the boundary area BDA by the separator SPR′. Accordingly, when the display panel DP operates, the current flowing from each of the first to third sub-pixels SP1 to SP3 to the adjacent sub-pixel through the layers included in the emission structure EMS' may be reduced. Accordingly, the first to third light-emitting elements LD1′ to LD3′ may operate with relatively high reliability.

In embodiments, the emission structure EMS' may include two light-emitting units that are sequentially stacked, and each of the light-emitting units may include an emission layer configured to generate light according to an applied current. In other embodiments, the emission structure EMS' may include three light-emitting units that are sequentially stacked, and each of the light-emitting units may include an emission layer configured to generate light according to an applied current. In these embodiments, a charge generation layer may be arranged between the light-emitting units.

In the embodiments, the emission structure EMS' may be formed through a process, such as vacuum deposition, inkjet printing, and the like.

A cathode electrode CE may be located on the emission structure EMS′. The cathode electrode CE may be provided in common to the first to third sub-pixels SP1 to SP3.

The first anode electrode AE1′, the portion of the emission structure EMS' overlapping the first anode electrode AE1′, and the portion of the cathode electrode CE overlapping the first anode electrode AE1′ may form in the first light-emitting element LD1′. The second anode electrode AE2′, a portion of the emission structure EMS' overlapping the second anode electrode AE2′, and a portion of the cathode electrode CE overlapping the second anode electrode AE2′ may form a second light-emitting element LD2′. The third anode electrode AE3′, a portion of the emission structure EMS' overlapping the third anode electrode AE3′, and a portion of the cathode electrode CE overlapping the third anode electrode AE3′ may form a third light-emitting element LD3′.

A thin film encapsulation layer TFE is located on the cathode electrode CE. The thin film encapsulation layer TFE may reduce or prevent penetration of oxygen and/or moisture into the light-emitting element layer LDL′.

An adhesive layer APL, an organic layer OL, and a cover window CW may be located on the thin film encapsulation layer TFE. The adhesive layer APL, the organic layer OL, and the cover window CW may be configured similarly to the adhesive layer APL, the organic layer OL, and the cover window CW of FIG. 16, respectively. Redundant descriptions thereof are omitted.

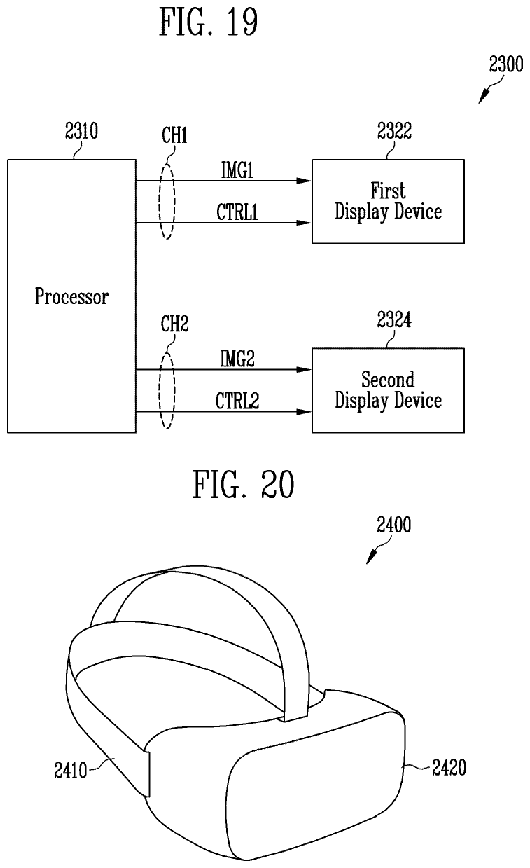

FIG. 19 is a drawing illustrating a display system 2300 according to embodiments of the present disclosure.

Referring to FIG. 19, the display system 2300 may include a processor 2310 and one or more display devices 2322 and 2324.

The processor 2310 may perform various tasks and calculations. In embodiments, the processor 2310 may include an application processor (AP), a graphics processing unit (GPU), a microprocessor, a central processing unit (CPU), and the like. The processor 2310 may be connected to other components of the display system 2300 via a bus system and control them.

In FIG. 19, the display system 2300 is illustrated as including first and second display devices 2322 and 2324. The processor 2310 may be connected to the first display device 2322 via a first channel CH1 and to the second display device 2324 via a second channel CH2.

Through the first channel CH1, the processor 2310 may transmit first image data IMG1 and a first control signal CTRL1 to the first display device 2322. The first display device 2322 may display an image based on the first image data IMG1 and the first control signal CTRL1. The first display device 2322 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 2310 may transmit the second image data IMG2 and the second control signal CTRL2 to the second display device 2324. The second display device 2324 may display an image based on the second image data IMG2 and the second control signal CTRL2. The second display device 2324 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 2300 may include a computing system that provides a video display function, such as a portable computer, a mobile phone, a smartphone, a tablet personal computer (PC), a smartwatch, a watch phone, a portable multimedia player (PMP), a navigation device, an ultra-mobile personal computer (UMPC), or similar devices. In addition, the display system 2300 may include at least one of a head-mounted display device, a virtual reality device, a mixed reality device, and an augmented reality device.

FIG. 20 is a perspective view illustrating an application example of the display system 2300 of FIG. 19.

Referring to FIG. 20, the display system 2300 of FIG. 19 may be applied to a head-mounted display device 2400. The head-mounted display device 2400 may be a wearable electronic device that may be worn on a user's head.

The head-mounted display device 2400 may include a head-mounted band 2410 and a display device receiving case 2420. The head-mounted band 2410 may be connected to the display device receiving case 2420. The head-mounted band 2410 may include a horizontal band and/or a vertical band for securing the head-mounted display device 2400 to the user's head. The horizontal band may be configured to surround the side of the user's head, and the vertical band may be configured to surround the upper part of the user's head. However, the embodiments are not limited thereto. For example, the head-mounted band 2410 may be implemented in the form of a glasses frame, a helmet, or the like.

The display device receiving case 2420 may receive the first and second display devices 2322 and 2324 of FIG. 19. The display device receiving case 2420 may further receive the processor 2310 of FIG. 19.

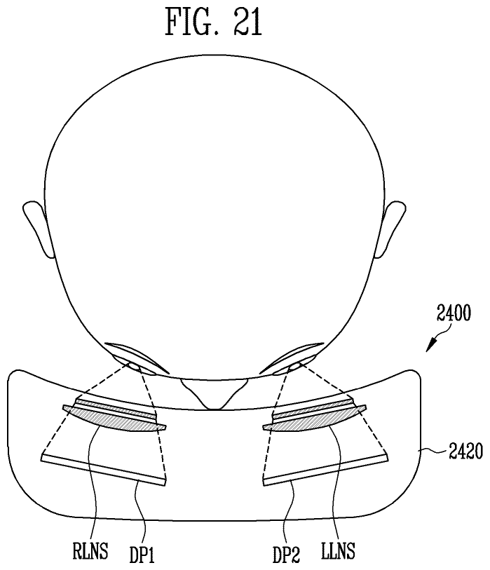

FIG. 21 is a drawing illustrating the head-mounted display device 2400 worn by a user.

Referring to FIG. 21, a first display panel DP1 of a first display device (e.g., the first display device 2322 in FIG. 19) and a second display panel DP2 of a second display device (e.g., the second display device 2324 in FIG. 19) may be arranged in the head-mounted display device 2400. The head-mounted display device 2400 may further include one or more lenses. For example, the head-mounted display device 2400 may include a left-eye lens LLNS and a right-eye lens RLNS.

In the display device receiving case 2420, the right-eye lens RLNS may be arranged between the first display panel DP1 and the user's right eye. In the display device receiving case 2420, the left-eye lens LLNS may be arranged between the second display panel DP2 and the user's left eye.

An image output from the first display panel DP1 may be shown to the user's right eye through the right-eye lens RLNS. The right-eye lens RLNS may refract light emitted from the first display panel DP1 toward the user's right eye. The right-eye lens RLNS may perform an optical function to adjust the viewing distance between the first display panel DP1 and the user's right eye.

An image output from the second display panel DP2 may be shown to the user's USR left eye through the left-eye lens LLNS. The left-eye lens LLNS may refract light emitted from the second display panel DP2 to be directed toward the user's left eye. The left-eye lens LLNS may perform an optical function to adjust the viewing distance between the second display panel DP2 and the user's left eye.

In embodiments, each of the right-eye lens RLNS and the left-eye lens LLNS may include an optical lens having a pancake-shaped cross-section. In embodiments, each of the right-eye lens RLNS and the left-eye lens LLNS may include a multi-channel lens including sub-areas having different optical characteristics. Each of the first and second display panels DP1 and DP2 may output images corresponding to the sub-areas of the multi-channel lens, and the output images may pass through the corresponding sub-areas and be shown to the user USR.

The right-eye lens RLNS may be implemented by applying the external lens (e.g., the external lens 610 in FIG. 4) described above. The left-eye lens LLNS may be implemented by applying the external lens 610 described above.

With further reference to FIG. 4 described above, the light emitted from the central area of the first display panel DP1 may be incident on the central area of the right-eye lens RLNS. The light emitted from the peripheral area (for example, the edge area) of the first display panel DP1 may be incident on the peripheral area (for example, the edge area) of the right-eye lens RLNS. The light emitted from the central area of the second display panel DP2 may be incident on the central area of the left-eye lens LLNS. The light emitted from a peripheral area (for example, an edge area) of the second display panel DP2 may be incident on a peripheral area (for example, an edge area) of the left-eye lens LLNS.

According to a display panel, a method of manufacturing the same, and an electronic device including the same according to embodiments of the present disclosure, it is possible to control an angle of emitted light.

The drawings and detailed description of the disclosed embodiments are merely examples of the present disclosure, and are used only to explain the present disclosure, and do not limit the meaning or scope of the present disclosure described in the claims. Therefore, those skilled in the art will understand that various modifications and other equivalent embodiments are possible. Therefore, the true technical scope of protection for the present discourse should be determined by the appended claims, with functional equivalents thereof to be included therein.

What is claimed is:

1. A display panel comprising:
a substrate;
a pixel circuit layer above the substrate, and comprising sub-pixel circuits of sub-pixels;
a light-emitting element layer above the pixel circuit layer, and comprising light-emitting elements of the sub-pixels;
an organic layer above the light-emitting element layer, and comprising refractive areas having different refractive indices above the light-emitting elements; and
a cover window above the organic layer.

2. The display panel according to claim 1, wherein the organic layer comprises:
a first area corresponding to a center of the substrate;
a third area corresponding to an edge of the substrate; and
a second area between the first area and the third area, and
wherein the refractive areas are arranged in different orders in the first area, the second area, and the third area.

3. The display panel according to claim 2, wherein the refractive areas in the first area are arranged in an order of a high refractive area, a middle refractive area, and a low refractive area in a direction away from a first one of the light-emitting elements in plan view.

4. The display panel according to claim 3, wherein a relationship between horizontal positions and corresponding ones of the refractive indices above the first one of the light-emitting elements in the first area follows an upward convex quadratic function in which a largest one of the corresponding ones of the refractive indices is in a central area.

5. The display panel according to claim 2, wherein the refractive areas in the second area are arranged in an order of a low refractive area, a high refractive area, and a middle refractive area in a direction away from a second one of the light-emitting elements in plan view.

6. The display panel according to claim 2, wherein the refractive areas in the third area are arranged in an order of a low refractive area, a middle refractive area, and a high refractive area in a direction away from a third one of the light-emitting elements in plan view.

7. The display panel according to claim 6, wherein a relationship between a horizontal position and corresponding ones of the refractive indices above the third one of the light-emitting elements follows a downward convex quadratic function in which a smallest of the corresponding ones of the refractive indices is in a central area.

8. The display panel according to claim 2, wherein the refractive indices range from about 1.4 to about 1.6.

9. The display panel according to claim 2, wherein the first area is configured to emit light in a normal direction of the substrate through the organic layer,
wherein the second area is configured to emit light at a first angle with respect to the normal direction through the organic layer, and
wherein the third area is configured to emit light at a second angle, which is greater than the first angle, with respect to the normal direction through the organic layer.

10. A method of manufacturing a display panel, the method comprising:
forming a pixel circuit layer comprising sub-pixel circuits of sub-pixels above a substrate;
forming a light-emitting element layer comprising light-emitting elements connected to the sub-pixel circuits above the pixel circuit layer;
forming an organic layer comprising refractive areas having different refractive indices above the light-emitting elements; and
arranging a cover window above the organic layer.

11. The method according to claim 10, wherein the forming of the organic layer comprises irradiating a mask having a pattern with ultraviolet rays, and curing the organic layer.

12. The method according to claim 11, wherein the curing of the organic layer comprises:
forming a low refractive area among the refractive areas by irradiating a first mask having a first pattern with ultraviolet rays for a first time; and
forming a high refractive area among the refractive areas by irradiating a second mask having a second pattern with ultraviolet rays for a second time that is longer than the first time.

13. The method according to claim 12, wherein the forming of the low refractive area comprises:
forming the low refractive area at a position relatively far from a first one of the light-emitting elements in a first area in plan view; and
forming the low refractive area at a position relatively close to a second one of the light-emitting elements in a second area in plan view,
wherein the first area corresponds to a center of the substrate, and
wherein the second area corresponds to an edge of the substrate.

14. The method according to claim 13, wherein a corresponding one of the refractive indices of the low refractive area is about 1.4 or more.

15. The method according to claim 12, wherein the forming of the high refractive area comprises:
forming the high refractive area at a position relatively close to a first one of the light-emitting elements in a first area in plan view; and
forming the high refractive area at a position relatively far from a second one of the light-emitting elements in a second area in plan view,
wherein the first area corresponds to a center of the substrate, and
wherein the second area corresponds to an edge of the substrate.

16. The method according to claim 15, wherein a corresponding one of the refractive indices of the high refractive area is about 1.6 or less.

17. The method according to claim 11, wherein the mask comprises a photoresist.

18. An electronic device comprising:
a processor;
a first display device configured to be controlled by the processor, and configured to display an image to a right eye; and
a second display device configured to be controlled by the processor, and configured to display an image to a left eye,
wherein the first display device and the second display device comprise an organic layer configured to emit light from light-emitting elements through refractive areas having different refractive indices.

19. The electronic device according to claim 18, wherein the first display device and the second display device comprises a display panel, the display panel comprising:
a substrate;
a pixel circuit layer above the substrate, and comprising sub-pixel circuits of sub-pixels;
a light-emitting element layer above the pixel circuit layer, and comprising the light-emitting elements of the sub-pixels; and
a cover window above the organic layer, and
wherein the organic layer is above the light-emitting element layer.

20. The electronic device according to claim 19, wherein the organic layer comprises:
a first area corresponding to a center of the substrate;
a third area corresponding to an edge of the substrate; and
a second area between the first area and the third area, and
wherein the refractive areas are arranged in different orders in the first area, the second area, and the third area.
